(19) United States
(12) Patent Application Publication
(10) Pub. No.: US 2024/0257671 A1
(43) Pub. Date: Aug. 1, 2024

(54) ELECTRONIC DEVICE

(71) Applicant: SEMICONDUCTOR ENERGY LABORATORY CO., LTD., Atsugi-shi, Kanagawa-ken (JP)

(72) Inventors: Shunpei YAMAZAKI, Setagaya, Tokyo (JP); Kenichi OKAZAKI, Atsugi, Kanagawa (JP); Satoru IDOJIRI, Tochigi, Tochigi (JP); Hiroki ADACHI, Tochigi, Tochigi (JP)

(21) Appl. No.: 18/559,819

(22) PCT Filed: Apr. 26, 2022
(86) PCT No.: PCT/IB2022/053836

§ 371 Date: Nov. 9, 2023

(30) Foreign Application Priority Data
May 13, 2021 (JP) 2021-081898
Jun. 4, 2021 (JP) 2021-094430
Feb. 8, 2022 (JP) 2022-017864

(51) Int. Cl. G09F 9/30; G09F 9/33

(52) U.S. Cl. CPC G09F 9/301; G09F 9/33

(57) ABSTRACT

One embodiment of the present invention provides a novel display apparatus that is highly convenient or reliable. The display apparatus includes a plurality of flexible substrates over each of which a plurality of light-emitting diode chips are mounted, a substrate provided with a nitride film, and a resin between the flexible substrates and the substrate provided with a nitride film. Light emitted from the light-emitting diode chips passes through the substrate provided with a nitride film.

### TECHNICAL FIELD

One embodiment of the present invention relates to an electronic device, a display apparatus, a method for manufacturing a display apparatus, and an apparatus for manufacturing a display apparatus.

Note that one embodiment of the present invention is not limited to the above technical field. Examples of a technical field of one embodiment of the present invention disclosed in this specification include a semiconductor device, a display apparatus, a light-emitting apparatus, a power storage device, a memory device, an electronic device, a lighting device, an input device, an input/output device, a driving method thereof, and a manufacturing method thereof.

Note that in this specification, a semiconductor device refers to every device that can function by utilizing semiconductor characteristics. A transistor, a semiconductor circuit, an arithmetic device, and a memory device are each one embodiment of the semiconductor device. In addition, an imaging device, an electro-optical device, a power generation device (including a thin film solar cell and an organic thin film solar cell), and an electronic device may include a semiconductor device.

### BACKGROUND ART

Uses for a display apparatus are diversified in recent years, and for example, the display apparatus is used for a portable information terminal, a television device for home use (also referred to as a TV or a television receiver), digital signage, and a PID (Public Information Display). Examples of the display apparatus include, typically, a display apparatus provided with a light-emitting element typified by an organic EL (Electro Luminescence) element or a light-emitting diode (LED), a display apparatus provided with a liquid crystal element, and electronic paper performing display by an electrophoretic method. In addition, the display apparatus is increasingly required to have high luminance for outdoor use.

Disclosed is an active matrix micro LED display apparatus that uses small LEDs (micro LEDs) as light-emitting elements and uses transistors as switching elements connected to pixel electrodes (Patent Documents 1, 2, 3, and 4).

### REFERENCES

### Patent Documents

[Patent Document 1] WO2020/065472

[Patent Document 2] WO2019/220265

[Patent Document 3] WO2020/049392

[Patent Document 4] WO2020/049397

### SUMMARY OF THE INVENTION

### Problems to be Solved by the Invention

A display apparatus in which micro LEDs are used as display elements needs a long time for mounting LEDs on a circuit board, and thus faces a challenge of reducing the manufacturing cost. As the number of pixels in the display apparatus increases, the number of LEDs to be mounted increases, and thus the time taken for mounting the LEDs becomes longer. Moreover, as the resolution of the display apparatus becomes higher, it becomes more difficult to mount LEDs.

In view of the above, an object of one embodiment of the present invention is to reduce the manufacturing cost of a display apparatus using a micro LED as a display element. Another object of one embodiment of the present invention is to provide a display apparatus using as a display element a micro LED with a relatively large area. Another object of one embodiment of the present invention is to provide a display apparatus having a display surface with a curved surface and using as a display element a micro LED with a relatively large area.

Another object of one embodiment of the present invention is to manufacture a display apparatus using a micro LED as a display element in a high yield.

An object of one embodiment of the present invention is to provide a display apparatus with high luminance. Another object of one embodiment of the present invention is to provide a display apparatus with high contrast. Another object of one embodiment of the present invention is to provide a display apparatus with high response speed. Another object of one embodiment of the present invention is to provide a display apparatus with low power consumption. Another object of one embodiment of the present invention is to provide a display apparatus manufactured at low cost. Another object of one embodiment of the present invention is to provide a display apparatus with long lifetime. Another object of one embodiment of the present invention is to provide a novel display apparatus.

Note that the description of these objects does not preclude the existence of other objects. Note that one embodiment of the present invention does not have to achieve all these objects. Note that objects other than these can be derived from the description of the specification, the drawings, and the claims.

### Means for Solving the Problems

A display apparatus for a component provided in an automobile is achieved by combining display apparatuses using as display elements a plurality of micro LEDs or a plurality of mini LEDs. Specifically, a display having a curved display surface is installed as a vehicle interior component of an automobile.

In one embodiment of the present invention, a flexible substrate is used and a plurality of micro LEDs or a plurality of mini LEDs are mounted over a wiring layer provided over the flexible substrate; then, the flexible substrate is fixed to a support having a curved surface, so that a display apparatus having a display surface with a curved surface is achieved. The curved surface of the support has a convex shape or a concave shape.

In order to improve yield, it is preferable that a certain number of micro LEDs be collectively manufactured using a flexible substrate and then a plurality of flexible substrates be combined to manufacture a display apparatus having one display surface.

In order to improve reliability, a display apparatus that uses as display elements a plurality of micro LEDs or a plurality of mini LEDs is interposed by one or two cover member(s) provided with a barrier film. A resin is provided between the cover member and a light-emitting element. When a light-transmitting material is used for the cover member and the resin, light from the light-emitting element can be emitted not only in one direction but also in two or more directions.

One embodiment of the present invention disclosed in this specification is a display apparatus including a plurality of flexible substrates over each of which a plurality of light-emitting diode chips (LED chips) are mounted, a substrate provided with a nitride film, and a resin between the flexible substrates and the substrate provided with a nitride film. Light emitted from the light-emitting diode chips passes through the substrate provided with a nitride film.

In the above structure, the flexible substrates, the substrate provided with a nitride film, or the resin preferably have (has) a light-transmitting property. Materials for the flexible substrates, the substrate provided with a nitride film, and the resin preferably have substantially the same refractive index. An interposing substrate for sealing means an acrylic resin and can be referred to as a cover member. The nitride film provided over the substrate means a silicon nitride film and can also be referred to as a barrier film. The difference in refractive index n between the cover member and the resin is preferably less than or equal to 20%, further preferably less than or equal to 10%, and still further preferably less than or equal to 5%. Note that the refractive index refers to an average refractive index with respect to visible light, specifically, light with a wavelength in the range from 400 nm to 750 nm. The average refractive index is a value obtained by dividing, by the number of measurement points, the sum of measured refractive indices with respect to light with wavelengths in the above range. Note that the refractive index of the air is 1.

Note that the flexible substrates and the substrate provided with a nitride film are referred to as substrates and may also be referred to as films depending on the material and the thickness.

In the above structure, the display apparatus disclosed in this specification is fixed to a support having a curved surface, and at least part of a display surface of the display apparatus can have a curved surface. In the case where the display apparatus is fixed to the support having a curved surface, the flexible substrates and the substrate provided with a nitride film preferably have a small thickness.

In order to increase area, a plurality of micro LEDs or a plurality of mini LEDs are mounted over each of a plurality of flexible substrates, and then the substrates are arranged in a tiled pattern, so that a display apparatus having one display surface is manufactured.

Before being arranged in a tiled pattern, the plurality of flexible substrates (or element layers) are cut with laser light. A projection portion and a depression portion are formed on end surfaces by the control of depth of laser light. As the laser light, continuous wave laser light or pulsed laser light can be used. In particular, the pulsed laser light is preferable because pulsed laser light with high energy can be emitted instantaneously. For the pulsed laser light, an Ar laser, a Kr laser, an excimer laser, a CO₂ laser, a YAG laser, a Y₂O₃ laser, a YVO₄ laser, a YLF laser, a YAlO₃, laser, a glass laser, a ruby laser, an alexandrite laser, a Ti: sapphire laser, a copper vapor laser, or a gold vapor laser can be used, for example. The wavelength of the laser light is preferably 200 nm to 20 μm. For example, as the laser light, a CO₂ laser with a wavelength of 10.6 μm can be used. The CO₂ laser can process a film or a glass substrate made of an organic material or an inorganic material. In the case where pulsed laser light is used as the laser light, the pulse width is preferably 10 ps (picoseconds) to 10 μs (microseconds), further preferably 10 ps to 1 μs, and still further preferably 10 ps to 1 ns (nanoseconds). For example, pulsed laser light with a wavelength of 532 nm and a pulse width of 1 ns or less is used.

One embodiment of the present invention disclosed in this specification is a method for manufacturing an electronic device including the steps of forming a first pixel region including first light-emitting diode chips over a first substrate and forming a second pixel region including second light-emitting diode chips over a second substrate. In the first pixel region, the plurality of first light-emitting diode chips are arranged so as to be adjacent to each other at an regular interval in a first direction. Before the second light-emitting diode chips in the second pixel region are aligned in the first direction so that the first light-emitting diode chips and the second light-emitting diode chips are arranged side by side, laser light scanning is performed in a second direction intersecting with the first direction, so that an end portion of the first substrate and an end portion of the first pixel region are partly cut to form a projection portion and an end portion of the second substrate and an end portion of the second pixel region are partly cut with the laser light to form a depression portion. The projection portion and the depression portion are engaged with each other, whereby the first pixel region and the second pixel region are fixed adjacent to each other.

In the above structure, the first light-emitting diode chips and the second light-emitting diode chips are fixed to a curved surface.

In the above structure, a transistor is provided between the second substrate and the first light-emitting diode chips.

In the above structure, the first substrate and the second substrate are each a flexible substrate.

In each of the above structures, the first light-emitting diode chips and the second light-emitting diode chips each include a light-emitting element. A light-emitting element emitting light of a first color, a light-emitting element emitting light of a second color, and a light-emitting element emitting light of a third color are mounted in a matrix in the pixel region. A plurality of kinds of light-emitting diode chips are arranged in a stripe pattern, a mosaic pattern, or a delta pattern. A light-emitting element emitting light of a single kind of color may be provided on one light-emitting diode chip, or light-emitting elements emitting light of three kinds of colors may be provided on one light-emitting diode chip.

One embodiment of the present invention disclosed in this specification is an electronic device including a display apparatus and a support. The display apparatus includes a plurality of light-emitting diode chips. The support includes a curved surface and a plurality of electrodes formed along the curved surface. The plurality of light-emitting diode chips are electrically connected to the plurality of electrodes.

A wiring layer may be formed in contact with the support. In that case, an electronic device has a structure in which a display apparatus and a support are provided, the display apparatus includes a plurality of light-emitting diode chips and a flexible substrate over which the plurality of light-emitting diode chips are mounted, the support includes a curved surface and a plurality of electrodes formed along the curved surface, the flexible substrate includes a wiring layer electrically connected to the plurality of electrodes, and the plurality of light-emitting diode chips are electrically connected to the plurality of electrodes through the wiring layer.

In each of the above structures, the plurality of light-emitting diode chips each include a light-emitting element. In the pixel region, a first light-emitting element and a second light-emitting element are adjacent to each other in the first direction, and the first light-emitting element and a third light-emitting element are adjacent to each other in the second direction. The second direction intersects with the first direction. The first light-emitting element and the second light-emitting element emit light of different colors, and the first light-emitting element and the third light-emitting element emit light of the same color.

In each of the above structures, a display apparatus having substantially high resolution can be provided by devised arrangement of light-emitting elements. In that case, the plurality of light-emitting diode chips each include a light-emitting element. In the pixel region, a first light-emitting element and a second light-emitting element are adjacent to each other in the first direction, the first light-emitting element and a third light-emitting element are adjacent to each other in the second direction, a fourth light-emitting element and a fifth light-emitting element are adjacent to each other in the first direction, the fourth light-emitting element and a sixth light-emitting element are adjacent to each other in the second direction, and the second light-emitting element and the fourth light-emitting element are adjacent to each other in the first direction. The second direction intersects with the first direction. The first to third light-emitting elements emit light of the same color, the fourth to sixth light-emitting elements emit light of the same color, and the fourth to sixth light-emitting elements emit light of a color different from the color of light emitted by the first to third light-emitting elements.

### Effect of the Invention

With one embodiment of the present invention, a display apparatus using as a display element a micro LED having a relatively large area can be achieved. With another embodiment of the present invention, a display apparatus having a display surface with a curved surface and using as a display element a micro LED with a relatively large area can be achieved.

With another embodiment of the present invention, the manufacturing cost of a display apparatus using a micro LED as a display element can be reduced. With another embodiment of the present invention, a display apparatus using a micro LED as a display element can be manufactured in a high yield.

Note that the description of these effects does not preclude the existence of other effects. Note that one embodiment of the present invention does not need to have all these effects. Note that effects other than these will be apparent from the description of the specification, the drawings, and the claims and can be derived from the description of the specification, the drawings, and the claims.

### BRIEF DESCRIPTION OF THE DRAWINGS

FIG. 1A to FIG. 1C are examples of cross-sectional views each illustrating a structure of one embodiment of the present invention.

FIG. 2A to FIG. 2D are examples of cross-sectional views each illustrating a step of one embodiment of the present invention.

FIG. 3A is a top view illustrating a pixel region before laser irradiation, and FIG. 3B is an example of a perspective view of an enlarged part of the pixel region.

FIG. 4 is an example of a top view illustrating one embodiment of the present invention.

FIG. 5A illustrates a part of a cross section of a display apparatus of one embodiment of the present invention, which uses as display elements micro LEDs each having a curved display surface, and

FIG. 5B is a cross-sectional perspective view of the display apparatus.

FIG. 6A1 and FIG. 6B1 are perspective views illustrating a method for manufacturing a display apparatus, and FIG. 6A2 and FIG. 6B2 are cross-sectional views illustrating the method for manufacturing a display apparatus.

FIG. 7A1 and FIG. 7B1 are perspective views illustrating a method for manufacturing a display apparatus, and FIG. 7A2 and FIG. 7B2 are cross-sectional views illustrating the method for manufacturing a display apparatus.

FIG. 8A1 and FIG. 8B1 are perspective views illustrating a method for manufacturing a display apparatus, and FIG. 8A2 and FIG. 8B2 are cross-sectional views illustrating the method for manufacturing a display apparatus.

FIG. 9A1 and FIG. 9B1 are perspective views illustrating a method for manufacturing a display apparatus, and FIG. 9A2 and FIG. 9B2 are cross-sectional views illustrating the method for manufacturing a display apparatus.

FIG. 10A1 and FIG. 10B1 are perspective views illustrating a method for manufacturing a display apparatus, and FIG. 10A2 and FIG. 10B2 are cross-sectional views illustrating the method for manufacturing a display apparatus.

FIG. 11 is a perspective view of an apparatus.

FIG. 12 is a schematic view illustrating a structure of the apparatus.

FIG. 13A to FIG. 13C are cross-sectional views illustrating a method for manufacturing a display device.

FIG. 14A to FIG. 14D are cross-sectional views illustrating a method for manufacturing a display device.

FIG. 15 is a schematic cross-sectional view of a modification example of the display apparatus.

FIG. 16A to FIG. 16C illustrate a structure example of a light-emitting element.

FIG. 17 is a diagram illustrating an example of a cross-sectional structure of a display apparatus.

FIG. 18A is a block diagram illustrating an example of a display apparatus. FIG. 18B to FIG. 18D are diagrams each illustrating an example of a pixel circuit.

FIG. 19A to FIG. 19D are diagrams each illustrating an example of a transistor.

FIG. 20 is a top view illustrating a structure example of a display apparatus.

FIG. 21A to FIG. 21D are diagrams each illustrating an example of a pixel. FIG. 21E and FIG. 21F are diagrams each illustrating a circuit diagram example of a pixel.

FIG. 22 is a diagram illustrating a structure example in a vehicle.

FIG. 23 is a diagram illustrating a structure example in a vehicle.

FIG. 24A and FIG. 24B are diagrams each illustrating one embodiment of a light-emitting apparatus.

### MODE FOR CARRYING OUT THE INVENTION

Embodiments of the present invention will be described in detail below with reference to the drawings. Note that the present invention is not limited to the following description, and it is readily understood by those skilled in the art that modes and details of the present invention can be modified in various ways. In addition, the present invention should not be construed as being limited to the description of the embodiments below.

### Embodiment 1

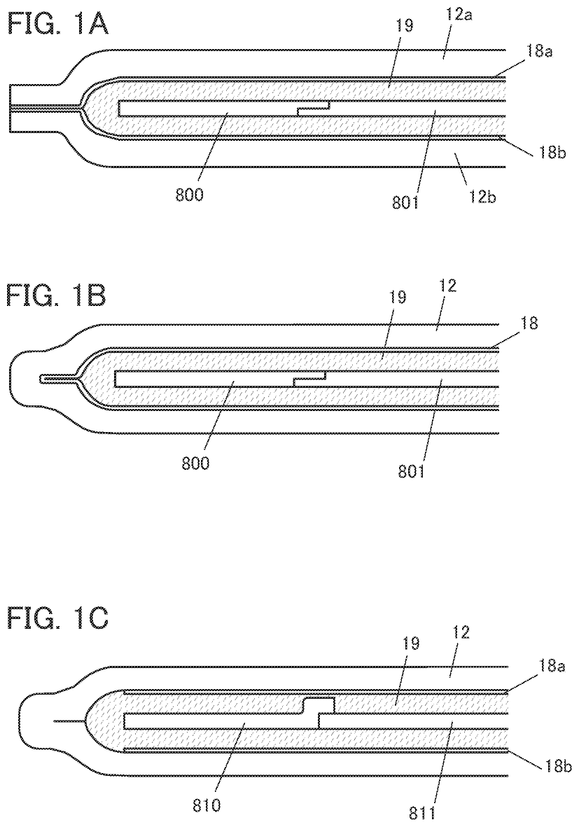

In this embodiment, a structure in which a plurality of flexible substrates over which a plurality of light-emitting diode chips are mounted are connected and sealed with a substrate provided with a nitride film will be described with reference to FIG. 1.

FIG. 1A is a cross-sectional view illustrating a structure of an end portion of a display apparatus. A flexible substrate 800 over which a plurality of light-emitting diode chips are mounted and a second substrate 801 over which a plurality of light-emitting diode chips are mounted are arranged side by side, surrounded and fixed by a resin 19, and further interposed between a third substrate 12a provided with a nitride film 18a and a fourth substrate 12b provided with a nitride film 18b. The nitride film 18a can be formed on the third substrate 12a by a sputtering method, a chemical vapor deposition (CVD) method, or a plasma-enhanced chemical vapor deposition (PECVD) method. Alternatively, an atomic layer deposition (ALD) method, which causes less deposition damage can also be used. The nitride films 18a and 18b may be a nitride insulating film, an oxynitride insulating film, or a nitride oxide insulating film; for example, a silicon nitride film, an aluminum nitride film, a silicon oxynitride film, an aluminum oxynitride film, a silicon nitride oxide film, or an aluminum nitride oxide film can be used. The thickness of each of the nitride films 18a and 18b is preferably greater than or equal to 1 nm and less than or equal to 500 nm.

Note that in this specification, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

The plurality of light-emitting diode chips provided over the flexible substrate 800 and the plurality of light-emitting diode chips provided over the second substrate 801 are arranged at a regular interval to form one pixel region.

The way of arranging the flexible substrate 800 and the second substrate 801 will be described in detail in Embodiment 2. Note that adjacent end surfaces of the flexible substrate 800 and the second substrate 801 are processed by laser light.

Although the flexible substrate 800 illustrated here has a flat plane, in the case where the flexible substrate 800 is fixed to a support having a curved surface, the flexible substrate 800 is preferably fixed while being curved along the curved surface. In that case, the whole display apparatus (including at least the flexible substrate 800, the second substrate 801, the resin 19, the third substrate 12a, and the fourth substrate 12b) is curved and fixed.

With the above structure, the third substrate 12a provided with the nitride film 18a and the fourth substrate 12b provided with the nitride film 18b can prevent entry of moisture from the outside, improving the reliability of the display apparatus.

Light from the light-emitting diode chips provided over the flexible substrate 800 is emitted in directions perpendicular to the substrate surface (two light-emitting directions opposite each other with the substrate surface therebetween). The resin 19 and the third substrate 12a on the path of at least one of the light-emitting directions preferably have light-transmitting properties.

Furthermore, display by light emission in the two directions can be performed when a light-transmitting material is used for all of the resin 19, the third substrate 12a, and the fourth substrate 12b, which overlap with the paths of the two light-emitting directions, i.e., a first emission path passing through the third substrate 12a and a second emission path passing through the fourth substrate 12b. Since the pixel region of the display apparatus has a light-transmitting property, what is called a see-through display apparatus can also be obtained.

FIG. 1B illustrates a modification example of FIG. 1A: sealing is performed by bending one substrate in FIG. 1B whereas sealing is performed with the two substrates in FIG. 1A. FIG. 1B is the same as FIG. 1A except that sealing is performed with one substrate, and thus uses the same reference numerals for the same components as those in FIG. 1A.

Sealing not with the two substrates but with a substrate 12 allows reducing of the number of components to lower manufacturing costs. In addition, the sealing with the substrate 12 improves the barrier property.

FIG. 1C illustrates an example different from those in FIG. 1A and FIG. 1B. In the example illustrated in FIG. 1C, an end portion of a flexible substrate 810 overlaps with an end portion of a second substrate 811. The bent substrate 12 is selectively provided with the nitride film 18a and the nitride film 18b.

Also in FIG. 1C, a plurality of light-emitting diode chips provided over the flexible substrate 810 and a plurality of light-emitting diode chips provided over the second substrate 811 are arranged at a regular interval to form one pixel region. An end surface of the flexible substrate 810 is a surface divided with laser light. The second substrate 811 includes an element layer, and end surfaces of the element layer and the second substrate 811 are also surfaces divided with laser light. The flexible substrate 810 and the second substrate 811 overlap with each other after the end portion of the substrate 810 is cut with laser light, so that display can be performed on the display apparatus with the boundary between the flexible substrate 810 and the second substrate 811 less noticeable.

An optical film may be provided additionally. For example, in the case where a light-emitting element that emits ultraviolet light is used for the light-emitting diode chips, a full-color display apparatus can be achieved by providing a color conversion layer. The color conversion layer may be provided on the path of a light-emitting direction; in the case of two light-emitting directions, two color conversion layers (or color conversion films) are provided so that the light-emitting diode chips are interposed therebetween. The color conversion layer (or color conversion film) is preferably provided between the flexible substrate 810 and the resin 19 because the alignment is important. A full-color display apparatus may be achieved by using a white-light-emitting diode chip and providing a color filter.

A circularly polarizing film may be provided as the optical film. The circularly polarizing film is preferably provided on one surface of the bent substrate 12. By providing the circularly polarizing film, display can be performed on the display apparatus with the boundary between the flexible substrate 810 and the second substrate 811 less noticeable.

At least part of this embodiment can be implemented in appropriate combination with the other embodiments described in this specification.

### Embodiment 2

In this embodiment, a display apparatus that is one embodiment of the present invention and a manufacturing method thereof will be described.

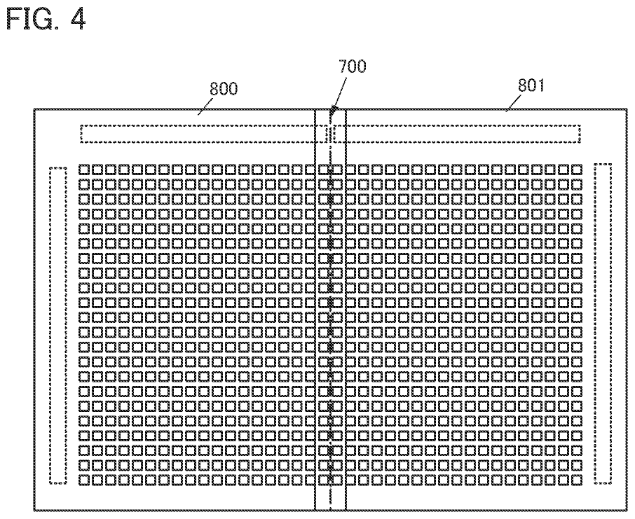

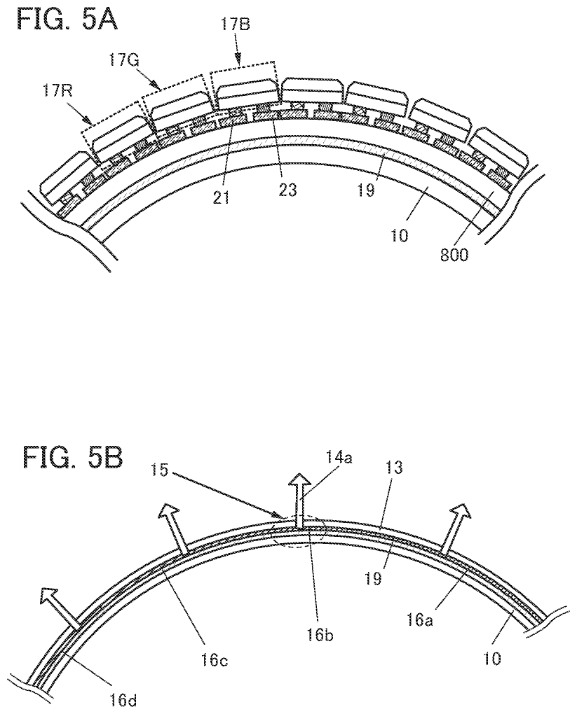

First, FIG. 4, FIG. 5A, and FIG. 5B illustrate an example of a display apparatus that can be manufactured by the method for manufacturing a display apparatus of one embodiment of the present invention. FIG. 4 illustrates an example of a top view of the display apparatus in which two pixel regions are formed over the respective flexible substrates (the substrate 800 and the second substrate 801) separated along a laser irradiation line 700.

Although FIG. 4 shows a diagram of a plane state, the display apparatus can also be fixed to a curved surface as illustrated in FIG. 5A and FIG. 5B.

In the display apparatus illustrated in FIG. 5A, the flexible substrate 800 is fixed to a support 10 having a curved surface with the resin 19 therebetween. A pixel region is formed over the flexible substrate 800, and a light-emitting element 17R, a light-emitting element 17G, and a light-emitting element 17B are provided in the pixel region. The light-emitting element 17R, the light-emitting element 17G, and the light-emitting element 17B are arranged in a stripe pattern, a mosaic pattern, or a delta pattern. A white-light-emitting element may be additionally provided so that the light-emitting elements with four colors are arranged.

The light-emitting element 17R, the light-emitting element 17G, and the light-emitting element 17B are micro LED chips that emit light of different colors, and a wiring layer is provided between the micro LED chips and the flexible substrate 800. Note that the wiring layer includes an electrode 21 and an electrode 23 which are connected to the light-emitting element 17R, the light-emitting element 17G, and the light-emitting element 17B.

Examples of the flexible substrate 800 include an acrylic resin, polyester resins typified by PET and PEN, a polyacrylonitrile resin, a polyimide resin, a polymethyl methacrylate resin, a PC resin, a PES resin, polyamide resins (such as nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a PTFE resin, and an ABS resin. In particular, a material with a low coefficient of linear expansion is preferred, and for example, a polyamide imide resin, a polyimide resin, a polyamide resin, and PET can be suitably used. A substrate in which a fibrous body is impregnated with a resin and a substrate whose coefficient of linear expansion is reduced by mixing an inorganic filler with a resin can also be used.

Alternatively, a metal film can be used as the flexible substrate 800. As the metal film, stainless steel or aluminum can be used. The metal film can withstand high heat temperature when the micro LED chips are mounted.

The flexible substrate 800 is preferably provided with a circuit for driving a light-emitting diode chip 17. For example, the circuit on the flexible substrate 800 is composed of a transistor, a capacitor, a wiring, and an electrode. It is further preferable to adopt an active matrix system by which each of the light-emitting element 17R, the light-emitting element 17G, and the light-emitting element 17B is connected to one or more transistors. In the pixel region, the transistor is electrically connected to the electrode 21 and the electrode 23.

FIG. 5A illustrates an example in which each of the light-emitting element 17R, the light-emitting element 17G, and the light-emitting element 17B is electrically connected to the two electrodes, the electrode 21 and the electrode 23, but one embodiment of the present invention is not limited thereto. Electrodes electrically connected to a pixel circuit may be formed in accordance with the number of electrodes included in the light-emitting element 17R, the light-emitting element 17G, and the light-emitting element 17B. Note that in this embodiment, the light-emitting element 17R, the light-emitting element 17G, and the light-emitting element 17B are illustrated as examples of components provided on the flexible substrate 800, and the light-emitting elements can be rephrased as light-emitting devices. Similarly, the capacitor may be rephrased as a capacitor device.

FIG. 5B illustrates an example of a cross-sectional view of the light-emitting apparatus that emits light. FIG. 5A corresponds to an enlarged view of a region 15 surrounded by a dashed line in FIG. 5B. Flexible substrates each including one pixel region are arranged over the support 10 in a tiled pattern, so that an increase in the area of the display surface can be achieved. In FIG. 5B, four light-emitting panels are fixed with the resin 19. For example, in order to obtain a full-color display apparatus, red-light-emitting elements, green-light-emitting elements, and blue-light-emitting elements are mounted in a matrix over one flexible substrate, so that a pixel region is formed and used as a light-emitting panel 16a. FIG. 5B also illustrates a light-emitting panel 16b adjacent to the light-emitting panel 16a, a light-emitting panel 16c adjacent to the light-emitting panel 16b, and a light-emitting panel 16d adjacent to the light-emitting panel 16c. In addition, a cover member 13 covering the four light-emitting panels is provided, making the boundary between pixel regions less noticeable. The cover member 13 is not necessarily provided if not particularly needed. The support 10 can also be referred to as a housing or a support member and includes a curved surface at least partly. In the case where the display apparatus is provided inside a vehicle, plastic, a metal, glass, or rubber is used for the support 10. Although the support has a plate-like shape here, there is no particular limitation on the shape of the support 10 and any member having a curved surface at least partly can be used. A wiring layer may be provided over the support 10, and a wiring included in the wiring layer is electrically connected to an electrode of the light-emitting panel. The wiring layer may include the wiring, an insulating film covering the wiring, and an electrode connected to the wiring through an opening formed in the insulating film. The wiring included in the wiring layer functions as an auxiliary wiring, a connection wiring, a power supply line, a signal line, or a fixed potential line. The wiring of the wiring layer may be formed over the support 10 having a curved surface by a known technique. For example, the wiring layer may be provided over the support 10 by a method for selectively forming a silver paste, a relocation method, or a transfer method.

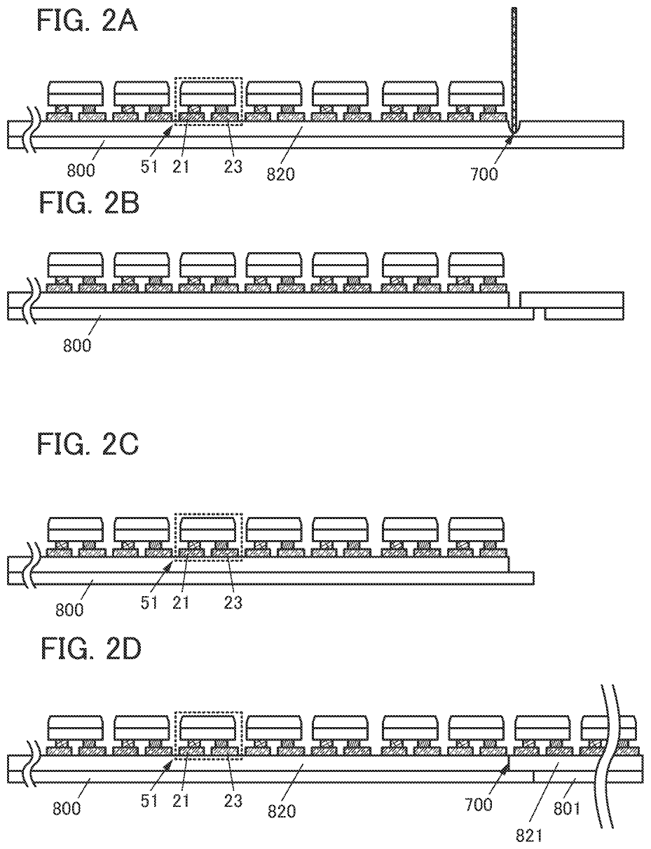

Next, a method for manufacturing a display apparatus by arranging the pixel regions provided over the two flexible substrates will be described with reference to FIG. 2.

FIG. 2A is a schematic cross-sectional view at the stage where an end portion is irradiated with laser light after light-emitting diode chips are mounted over the flexible substrate 800. An element layer 820 including an electrode or a transistor is formed over the flexible substrate 800 in advance, and a plurality of kinds of light-emitting diode chips are arranged in a matrix at a regular interval. In view of handling, the element layer 820 or the light-emitting diode chips are difficult to be provided in the periphery of the flexible substrate 800; accordingly, no element is formed in part of the periphery of the flexible substrate 800. Thus, laser light irradiation is performed to cut part of the element layer 820 (an end portion of the pixel region) along the laser irradiation line 700 with respect to the element layer 820. The position of the laser irradiation line 700 with respect to the element layer 820 is shifted in parallel to cut part of the flexible substrate 800. Note that a structure in which the element layer 820 does not include an LED is described here; however, the structure is not particularly limited and the element layer 820 is referred to as the element layer 820 including an LED.

FIG. 2B illustrates a state after irradiation. Scanning is performed while the depth of the position irradiated with laser light is controlled, so that part of the flexible substrate 800 is removed to form a projection portion on an end surface of the flexible substrate 800 as illustrated in FIG. 2C.

Then, another substrate (the second substrate 801) is also irradiated with laser light, and the position of the laser irradiation line with respect to the element layer 821 is shifted from that with respect to an end surface of the second substrate 801, whereby a depression portion is formed on the end surface of the second substrate 801.

The flexible substrate 800 as the first substrate and the second substrate 801 are combined as illustrated in FIG. 2D; thus, the light-emitting diode chips can be arranged in one direction at a regular interval. A top view at this stage corresponds to FIG. 4.

When the projection portion of the flexible substrate 800 and the depression portion of the second substrate 801 are engaged with each other, the adhesion area is increased and fixing is facilitated. Furthermore, the light-emitting diode chips can be fixed so as to be arranged in one direction at a regular interval even with a small distance therebetween. As a result, a display apparatus with a large area can be manufactured. An element layer 821 provided over the second substrate 801 may be configured such that a wiring or an electrode included in the element layer 821 is electrically connected to the wiring or the electrode included in the element layer 820 provided over the flexible substrate 800.

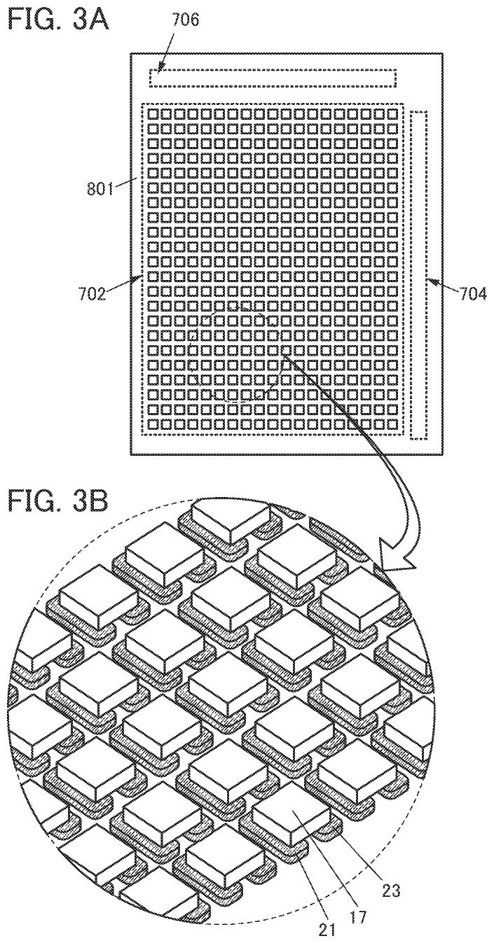

FIG. 3A is a top view of the display apparatus before laser irradiation. In the display apparatus illustrated in FIG. 3A, a pixel region 702, a source driver circuit portion 706, and a gate driver circuit portion 704 are provided over the flexible substrate 801 as the first substrate. The pixel region 702, the source driver circuit portion 706, and the gate driver circuit portion 704 can be provided in the element layer provided over the flexible substrate 800. The source driver circuit portion 706 and the gate driver circuit portion 704 may be mounted as driver ICs. As illustrated in FIG. 3B, a plurality of light-emitting diode chips 17 are provided in the pixel region 702. The plurality of light-emitting diode chips 17 are three or four kinds of light-emitting elements and are arranged so that a full-color display apparatus can be achieved. The light-emitting diode chips 17 are each connected to the electrodes 21 and 23 of the element layer.

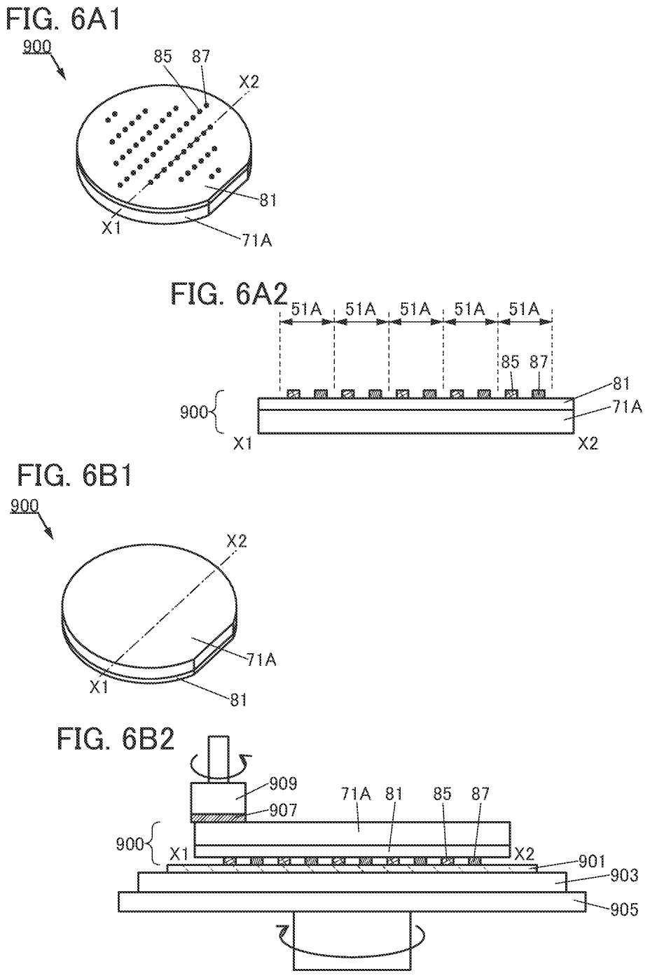

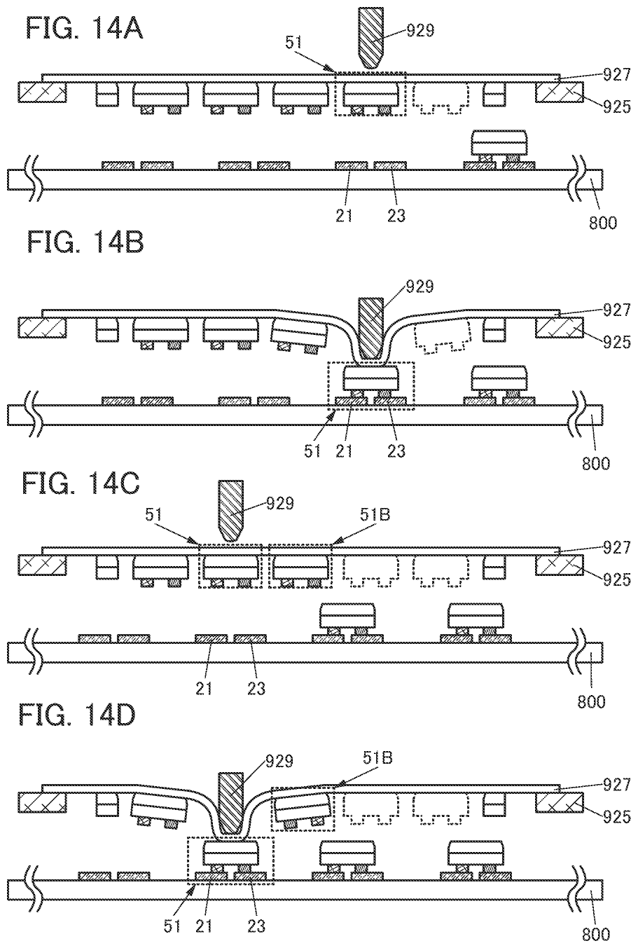

Next, the method for manufacturing the display apparatus is described with reference to FIG. 6A1 to FIG. 14D. FIG. 6A1 to FIG. 14D are perspective views and cross-sectional views illustrating steps in the method for manufacturing the display apparatus.

Note that an emission color of the LED chip that can be used in the method for manufacturing a display apparatus of one embodiment of the present invention is not particularly limited. For example, application to an LED chip emitting white light is possible. In addition, for example, application to an LED chip emitting light with a wavelength region of visible light of red, green, or blue is possible. Furthermore, for example, application to an LED chip emitting light with a wavelength region of near infrared light, infrared light, or ultraviolet light is possible. In the case of using an LED chip emitting light with a wavelength region of near infrared light, infrared light, or ultraviolet light, only one kind of LED chip is provided and a color conversion layer or a color conversion film is provided thereover. Since the surface of the display apparatus at the vicinity of the boundary between the flexible substrate 800 and the second substrate 801 is almost flat in this structure, the color conversion layer or the color conversion film can be suitably provided thereover with no unevenness on its surface.

In this embodiment, a micro LED having a double heterojunction is described. Note that there is no particular limitation on the light-emitting diode, and for example, a micro LED having a quantum well junction or a nanocolumn LED may be used.

The area of a light-emitting region of the light-emitting diode is preferably less than or equal to 1 mm², further preferably less than or equal to 10000 μm², still further preferably less than or equal to 3000 μm², and even further preferably less than or equal to 700 μm². The area of the region is preferably greater than or equal to 1 μm², further preferably greater than or equal to 10 μm², and still further preferably greater than or equal to 100 μm².

Note that the LED that can be used for the display apparatus of one embodiment of the present invention is not limited to the above-described micro LED. For example, a light-emitting diode having a light-emitting area of greater than 10000 μm² (also referred to as a mini LED) may be used. Note that the mini LED refers to a light-emitting diode having a chip size with a flat rectangular shape at least one side of which is greater than or equal to 0.1 mm.

The display apparatus of this embodiment preferably includes a transistor including a channel formation region in a metal oxide layer. The transistor using a metal oxide layer can have low power consumption. Thus, a combination with a micro LED can achieve a display apparatus with significantly reduced power consumption. The micro LED refers to a light-emitting diode having a chip size with a flat rectangular shape at least one side of which is less than 0.1 mm.

An LED chip substrate is provided with a plurality of LED chips. FIG. 6A1 and FIG. 6A2 illustrate an example of an LED chip substrate 900. FIG. 6A1 is a perspective view of the LED chip substrate 900, and FIG. 6A2 is a cross-sectional view taken along a dashed-dotted line X1-X2 in FIG. 6A1. As an LED chip, a semiconductor layer 81 including an n-type semiconductor layer, a light-emitting layer, and a p-type semiconductor layer, an electrode 85 functioning as a cathode, and an electrode 87 functioning as an anode are formed over a substrate 71A. A plurality of LED chips are formed on the LED chip substrate 900, and the LED chip substrate 900 is separated along LED chip compartments 51A, whereby a plurality of LED chips can be obtained.

The substrate 71A of the LED chip substrate 900 is ground to make the substrate 71A thin to have a desired thickness (FIG. 6B1 and FIG. 6B2). By reducing the thickness of the substrate 71A, separation into the LED chips becomes easy. Alternatively, the substrate 71A may be removed from the LED chip substrate 900 not by grinding but with laser light irradiation.

The details of the grinding are described. First, the LED chip substrate 900 on the electrode 85 and the electrode 87 side is attached to a plate 903. The LED chip substrate 900 and the plate 903 which have been attached are put on a table 905. At this time, the plate 903 side is in contact with the table 905, and the LED chip substrate 900 and the plate 903 are fixed to the table 905 with a vacuum chuck. Next, the substrate 71A is ground by being in contact with a grinding stone 907 provided on a grinding stone wheel 909 while the table 905 is rotated in a plane of the table 905, whereby a substrate 71 is formed. In the grinding, the grinding stone wheel 909 and the grinding stone 907 may be rotated.

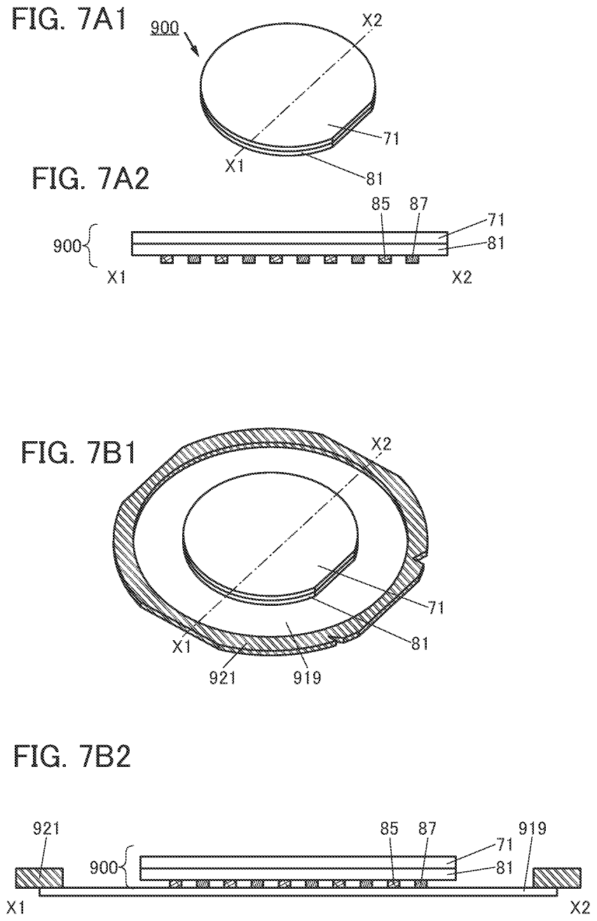

Next, a surface of the substrate 71 is preferably planarized by polishing the ground surface with an abrasive (also referred to as slurry) (FIG. 7A1 and FIG. 7A2). By planarizing the surface of the substrate 71, the yield in the following steps can be prevented from decreasing.

When the grinding and polishing are performed, it is preferable to provide and fix a film 901 for protection on the electrode 85 and the electrode 87 side and then perform the polishing (see FIG. 6B2). After the polishing, the film 901 is removed.

Next, a first film 919 is provided on the electrode 85 and the electrode 87 side, and the LED chip substrate 900 and the first film 919 are fixed to a first fixture 921 (FIG. 7B1 and FIG. 7B2). As the first film 919, a film having a property of stretching by being pulled (also referred to as an expand film) is preferably used. For the first film 919, a vinyl chloride resin, a silicone resin, or a polyolefin resin can be used. It is preferable that the first film 919 be provided with an adhesive on its surface and the adhesion be weakened when the adhesive is irradiated with light. Specifically, a film whose adhesion decreases when being irradiated with ultraviolet light can be suitably used as the first film 919. As the first fixture 921, a ring-like jig illustrated in FIG. 7B1 can be favorably used, for example.

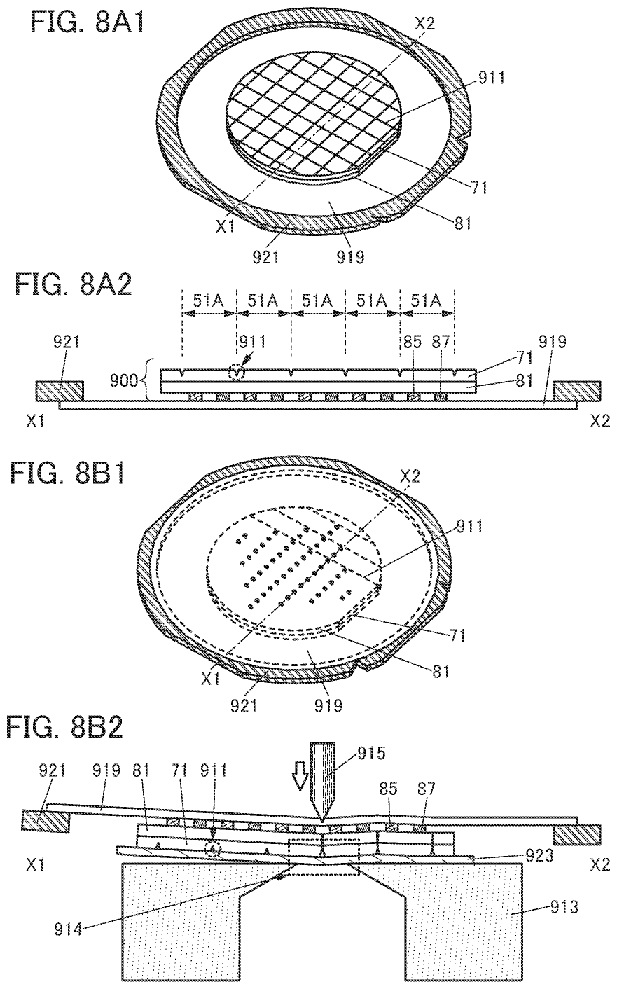

Next, scribe lines 911 are formed along the LED chip compartments 51A of the LED chip substrate 900 (FIG. 8A1 and FIG. 8A2). For the formation of the scribe lines 911, a machine scribing method can be used. In the machine scribing method, a scribing tool is pressed against the substrate 71, whereby a groove (also referred to as a scribe line or scribing) is mechanically formed on the substrate 71. As the scribing tool, a diamond blade can be used.

For the formation of the scribe lines 911, a laser scribing method may be used. By the laser scribing method, the substrate 71 is irradiated with laser light to be locally heated, and then rapidly cooled down to generate thermal stress that causes an altered layer on the substrate 71, whereby the scribe line 911 is formed. In the laser scribing method, the scribe line 911 may be formed on a surface of the substrate 71 or an inner side than the surface of the substrate 71. Although the machine scribing method needs replacement of scribing tools because the scribing tool is worn away, the laser scribing method does not need replacement of scribing tools.

Alternatively, the substrate 71 may be cut along the LED chip compartments 51A by a blade dicing method. In the blade dicing method, a blade is rotated at high speed to cut an object, and diamond can be used for the blade. In the case of using the blade dicing method, half-cut, in which the substrate 71 is cut to a predetermined depth in the thickness direction, may be employed, or full-cut, in which the substrate 71 and the semiconductor layer 81 are completely cut in the thickness direction, may be employed.

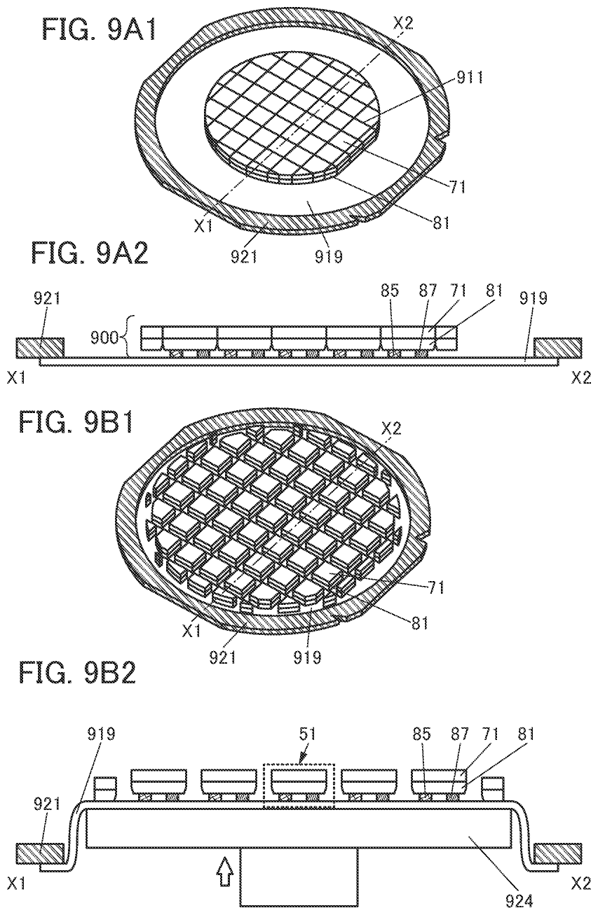

Next, the LED chip substrate 900 is divided into LED chips. For the division into LED chips, for example, the LED chip substrate 900 is put on a base 913 with an opening portion 914, and the blade 915 is driven along the scribe line 911, whereby the LED chip substrate 900 can be divided into LED chips (FIG. 8B1 and FIG. 8B2). Alternatively, the LED chip substrate 900 may be divided into LED chips in such a manner that the LED chip substrate 900 is interposed between rollers having surfaces with different inclination angles. Note that in the division into LED chips, a sheet 923 for protection (also referred to as a scribing sheet) may be provided on the substrate 71 side before the LED chip substrate 900 is divided into LED chips. FIG. 9A1 and FIG. 9A2 illustrate the LED chip substrate 900 after being divided into LED chips.

Next, the first film 919 is pulled to separate the LED chips 51 and widen the distance between the LED chips 51 (FIG. 9B1 and FIG. 9B2). Widening the distance between the LED chips 51 facilitates the following handling. In order to separate the LED chips 51, for example, a plate 924 having a larger area than a region where the LED chips 51 are provided is pushed up from the first film 919 side to the LED chip 51 side; accordingly, the first film 919 is pulled and thus the LED chips 51 can be separated.

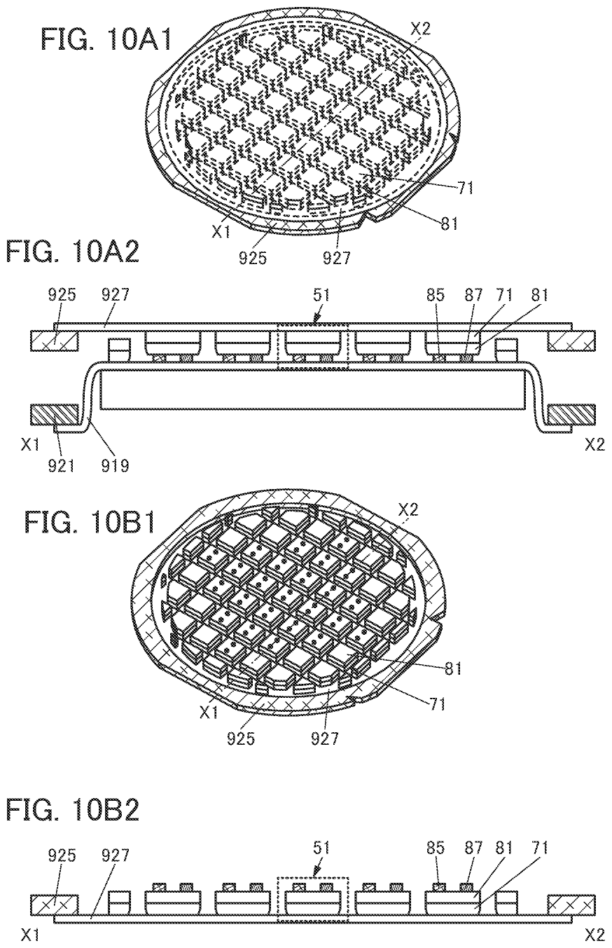

Next, a second film 927 is fixed to a second fixture 925, and the second film 927 and the second fixture 925 are provided on the substrate 71 side (FIG. 10A1 and FIG. 10A2).

Note that in the case where the LED chips 51 which have already been separated are used, manufacturing of the display apparatus may be started from the steps illustrated in FIG. 10A1 and FIG. 10A2. The separated LED chips 51 on the substrate 71 side are provided with the second film 927 and the second film 927 is fixed to the second fixture 925, and then the process can go to the next step. At this time, the LED chips 51 are preferably apart from each other as illustrated in FIG. 10A1 and FIG. 10A2, in which case the accuracy of the following mounting process is increased and thus the display apparatus can be manufactured in a high yield. Furthermore, by arranging a large number of LED chips 51 in a matrix in the second film 927, the manufacturing cost for the following mounting process can be reduced.

Next, irradiation with ultraviolet light is performed from the first film 919 side, whereby the first film 919 and the first fixture 921 are separated from the LED chips 51 (FIG. 10B1 and FIG. 10B2). In the step of separating the LED chips, the first film 919 is lengthened to be warped in some cases. When the LED chips 51 are separated from the first film 919 and fixed to the second film 927 again, the second film 927 can have less deflection. The second film 927 with less deflection increases the accuracy of the following mounting process, so that the display apparatus can be manufactured in a high yield.

As the second film 927, a film having elasticity is preferably used. The film having elasticity changes in shape when force is applied and returns back to the original shape when the force is removed. As the second film 927, a film with a high tensile modulus of elasticity can be suitably used. For the second film 927, a polyamide resin, a polyimide resin, or a polyethylene naphthalate resin can be used. Furthermore, the second film 927 preferably has high heat resistance. With an adhesive provided on the surface of the second film 927, the LED chip substrate 900 can be fixed to the second film 927. As the second fixture 925, a ring-like jig as illustrated in FIG. 10B1 can be suitably used, for example.

Here, inspection of the LED chip 51 is preferably performed. As the inspection of the LED chip 51, an appearance inspection can be used. Voltage may be applied between the electrode 85 and the electrode 87 to examine a light-emitting state from the LED chip 51. As to the LED chip 51 which has been determined as a defective by the inspection, it is preferable to acquire location information in the second film 927. By acquiring the location information of a defective, the defective can be removed from objects to be mounted in the following mounting process.

Next, a method for mounting the LED chips 51 over the flexible substrate 800 with use of a conductive paste, e.g., solder, is described.

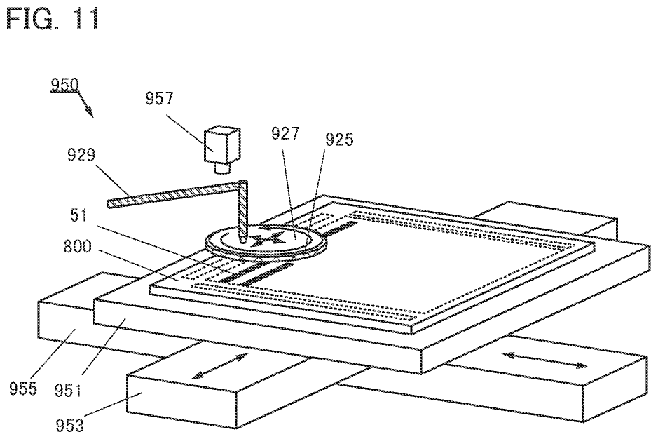

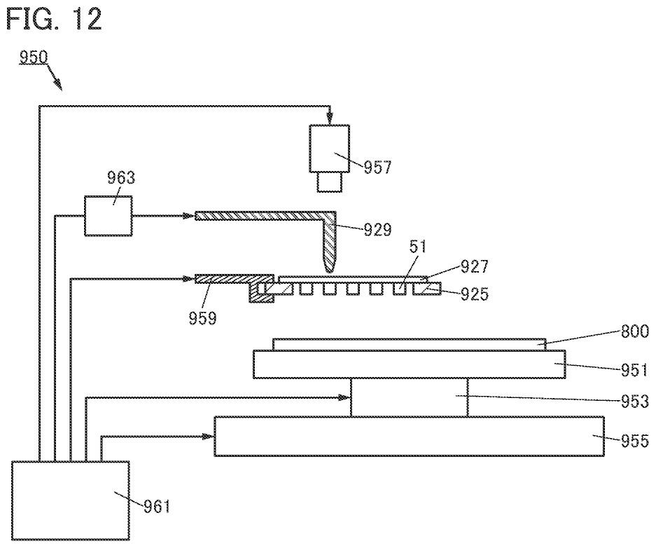

FIG. 11 and FIG. 12 illustrate an example of an apparatus 950 which can be used for a step of mounting the LED chips 51 over the flexible substrate 800. FIG. 11 is a perspective view of the apparatus 950, and FIG. 12 is a schematic view illustrating a structure of the apparatus 950. The apparatus 950 includes a stage 951, an X-axis one-axis robot 953, a Y-axis one-axis robot 955, a grasping mechanism 959, an extrusion mechanism 929, and a control device 961.

The stage 951 has a function of fixing the flexible substrate 800. For fixing of the flexible substrate 800, a vacuum suction mechanism can be used, for example. The stage 951 can move in the X and Y directions on a plane parallel to the surface of the flexible substrate 800 with use of the one-axis robot 953 and the one-axis robot 955.

The grasping mechanism 959 grasps the second fixture 925 that fixes the LED chip 51 and the second film 927. The grasping mechanism 959 also has a function of transferring the second fixture 925, which fixes the LED chip 51 and the second film 927, to a given position.

The extrusion mechanism 929 moves vertically and has a function of arranging the LED chips 51 over the substrate 800. The extrusion mechanism 929 may have a columnar shape (including a cylindrical shape and a polygonal column shape), and may have a shape in which the side in contact with the LED chip 51 is narrower. An end of the extrusion mechanism 929 in contact with the LED chip 51 preferably has a diameter smaller than the width of the LED chip 51.

The control device 961 has a function of controlling the one-axis robot 953, the one-axis robot 955, the grasping mechanism 959, and the extrusion mechanism 929. Furthermore, the control device 961 takes in the location information of the LED chip determined as a defective in the above inspection step for the LED chips 51. The control device 961 takes in the location information of a defective, whereby defectives can be removed from objects to be mounted.

The apparatus 950 is preferably provided with an alignment mechanism such as a camera 957. The position of the second fixture 925 is adjusted using, for example, an alignment marker provided on the flexible substrate 800 as a reference.

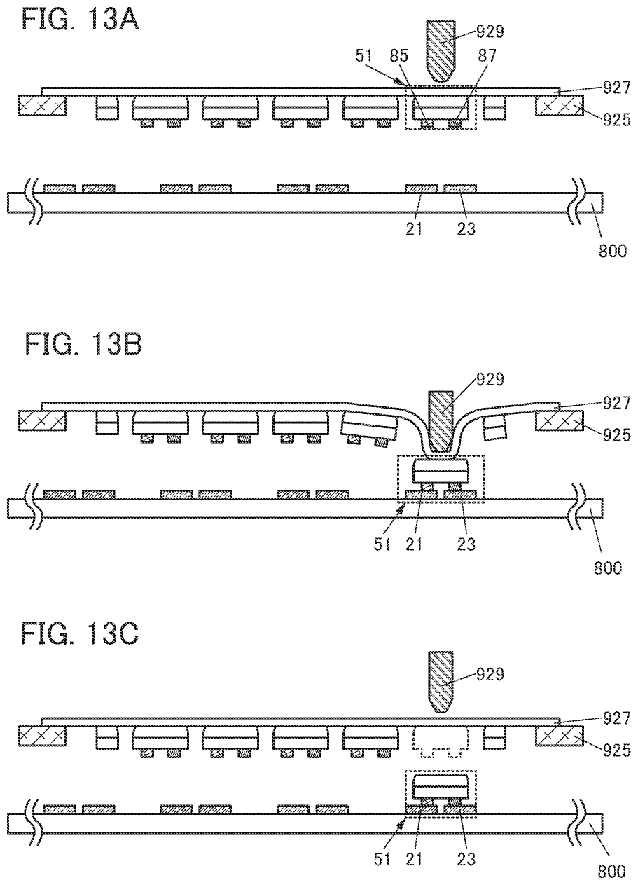

A method for mounting the LED chips 51 over the flexible substrate 800 is described in detail with reference to FIG. 13 and FIG. 14.

First, the plurality of LED chips 51 fixed to the second film 927 and the flexible substrate 800 are opposed to each other. At this time, it is preferable that the outline of the LED chip 51 be detected by the camera 957 and the location information of the LED chip 51 be acquired. According to the location information of the LED chip 51, the position of the LED chip 51 is adjusted by the grasping mechanism 959, so that the positions of the electrode 85 and the electrode 87 of the LED chip 51 are aligned with the positions of the electrode 21 and the electrode 23 over the flexible substrate 800 (FIG. 13A). The grasping mechanism 959 preferably moves on a plane parallel to the surface of the flexible substrate 800 in the X direction, the Y direction, and the θ direction. Moving in the X direction, the Y direction, and the θ direction enables highly accurate adjustment between the positions of the electrode 85 and the electrode 87 of the LED chip 51 and the positions of the electrode 21 and the electrode 23 over the flexible substrate 800.

Note that FIG. 12 illustrates a structure in which the camera 957 is provided above the second film 927 and detects the positions of the electrode 85 and the electrode 87 of the LED chip 51 from above the second film 927, but one embodiment of the present invention is not limited thereto. A camera (not illustrated) may be further provided below the flexible substrate 800 to detect, from below the flexible substrate 800, the positions of the electrode 85 and the electrode 87 of the LED chip 51 and the positions of the electrode 21 and the electrode 23 over the flexible substrate 800.

Next, the extrusion mechanism 929 is pressed from the second film 927 side in the direction of the flexible substrate 800 so that the electrode 85 and the electrode 21 are in contact with each other and the electrode 87 and the electrode 23 are in contact with each other. Then, an ultrasonic wave is applied to the extrusion mechanism 929, whereby the electrode 85 and the electrode 21 are pressure-bonded and the electrode 87 and the electrode 23 are pressure-bonded (FIG. 13B). Alternatively, the extrusion mechanism 929 may be heated so that the electrode 85 and the electrode 21 are bonded and the electrode 87 and the electrode 23 are bonded by thermocompression. Alternatively, pressure-bonding may be performed by an ultrasonic wave and heating. Note that in the case where the extrusion mechanism 929 is heated, the temperature of the extrusion mechanism 929 is preferably lower than or equal to the upper-temperature limit of the second film 927. By setting the temperature of the extrusion mechanism 929 lower than or equal to the upper-temperature limit of the second film 927, the second film 927 can be prevented from being deformed and warped.

The extrusion mechanism 929 is connected to a unit 963 illustrated in FIG. 12. The unit 963 includes an ultrasonic oscillator and can apply an ultrasonic wave to the extrusion mechanism 929. Alternatively, the unit 963 includes a heating mechanism and can apply heat to the extrusion mechanism 929. Alternatively, the unit 963 may include an ultrasonic oscillator and a heating mechanism, and may apply an ultrasonic wave and heat to the extrusion mechanism 929. The unit 963 is connected to the control device 961, and the control device 961 controls the timings of application of an ultrasonic wave and heating.

Note that conductive bumps may be provided over the electrode 21 and the electrode 23, and the LED chips 51 may be in contact with the bumps.

Next, the extrusion mechanism 929 is took away from the second film 927 (FIG. 13C). The electrode 85 and the electrode 21 are pressure-bonded and the electrode 87 and the electrode 23 are pressure-bonded, whereby the LED chip 51 mounted over the electrode 21 and the electrode 23 is separated from the second film 927. The adhesion of the adhesive provided on the surface of the second film 927 is preferably lower than the pressure bonding force between the electrode 85 and the electrode 21 and the pressure bonding force between the electrode 87 and the electrode 23. With use of such an adhesive having an adhesion lower than the pressure bonding force for the second film 927, the LED chip 51 can be mounted over the flexible substrate 800 efficiently and thus the manufacturing cost of the display apparatus can be reduced.

Here, when the second film 927 is warped, it is difficult to align the positions of the electrode 85 and the electrode 87 of the LED chip 51 with the positions of the electrode 21 and the electrode 23 over the flexible substrate 800, which might cause defective conduction between the electrodes 85 and 87 and the electrodes 21 and 23. In one embodiment of the present invention, the second film 927 has elasticity, and when the extrusion mechanism 929 is took away from the second film 927, the second film 927 can return to its original shape. Since the second film 927 returns to its original shape and can be inhibited from being warped, adjustment of the positions of the electrodes 85 and 87 and the positions of the electrodes 21 and 23 can be performed with high accuracy. The tensile modulus of elasticity of the second film 927 is preferably greater than or equal to 3 GPa and less than or equal to 18 GPa, further preferably greater than or equal to 5 GPa and less than or equal to 16 GPa, and still further preferably greater than or equal to 7 GPa and less than or equal to 14 GPa. By setting the tensile modulus of elasticity of the second film 927 within the above-mentioned range, the second film 927 can moderately stretch when the LED chip 51 is in contact with the electrode 21 and the electrode 23, and the warping of the second film 927 can be suppressed when the positional adjustment of the LED chip 51 is performed, whereby the display apparatus can be manufactured in a high yield and the manufacturing cost can be reduced.

Next, the position of the LED chip 51 fixed to the second film 927 is aligned with the positions of the electrode 21 and the electrode 23 which are not provided with the LED chip 51 (FIG. 14A). One or more of the stage 951, the grasping mechanism 959, and the extrusion mechanism 929 can be configured to be moved at the time of the positional adjustment. It is preferable to move two or more of the stage 951, the grasping mechanism 959, and the extrusion mechanism 929. With the configuration in which two or more of the stage 951, the grasping mechanism 959, and the extrusion mechanism 929 are moved, the accuracy of aligning the positions of the electrode 85 and the electrode 87 of the LED chip 51 with the positions of the electrode 21 and the electrode 23 over the flexible substrate 800 can be increased.

Next, the extrusion mechanism 929 is pressed from the second film 927 side in the direction of the flexible substrate 800 so that the electrode 85 and the electrode 21 are in contact with each other and the electrode 87 and the electrode 23 are in contact with each other. Then, the electrode 85 and the electrode 21 are pressure-bonded and the electrode 87 and the electrode 23 are pressure-bonded (FIG. 14B). After that, the extrusion mechanism 929 is moved above the second film 927. Thus, the LED chip 51 mounted over the electrode 21 and the electrode 23 is separated from the second film 927 (FIG. 14C).

The above-described operations are repeated, whereby the LED chips are mounted over the entire surface of the pixel region of the flexible substrate 800. Note that the location information of an LED chip 51B which has been determined as a defective in the inspection step for the LED chips 51 is taken into the control device 961, and the defective LED chip 51B is not mounted over the flexible substrate 800 (FIG. 14C and FIG. 14D). Since the position of the defective LED chip is taken into the control device 961, only non-defective LED chips 51 can be mounted over the flexible substrate 800. A step of performing reflow under a nitrogen atmosphere to dissolve solder and generate an alloy may be added after the mounting step.

By the method for manufacturing a display apparatus of one embodiment of the present invention, a plurality of kinds of LED chips 51 which emit colors in different wavelength regions can be provided over the flexible substrate 800. For example, the case where the LED chip 51 that emits light in a red wavelength region (hereinafter referred to as red light), the LED chip 51 that emits light in a green wavelength region (hereinafter referred to as green light), and the LED chip 51 that emits light in a blue wavelength region (hereinafter referred to as blue light) are provided over the flexible substrate 800 is described. With the use of the second film 927 and the second fixture 925 to which the plurality of LED chips 51 emitting red light are fixed, the LED chips 51 are mounted over the flexible substrate 800. Next, with the use of the second film 927 and the second fixture 925 to which the plurality of LED chips 51 emitting green light are fixed, the LED chips 51 are mounted over the flexible substrate 800. Next, with the use of the second film 927 and the second fixture 925 to which the plurality of LED chips 51 emitting blue light are fixed, the LED chips 51 are mounted over the flexible substrate 800. In this manner, the LED chips 51 which emit red light, the LED chips 51 which emit green light, and the LED chips 51 which emit blue light can be provided over the flexible substrate 800. Note that the order of mounting the LED chips is not particularly limited depending on the kinds.

Note that the case where the LED chips 51 are mounted over the flexible substrate 800 with use of a set of the second film 927 and the second fixture 925 is described as an example, but one embodiment of the present invention is not limited thereto. The LED chips 51 may be mounted with use of a plurality of sets of the second film 927 and the second fixture 925. Such a structure enables the display apparatus to be manufactured with high productivity. The LED chip 51 that emits light of a single color functions as a subpixel, a plurality of kinds of LED chips 51 constitute one pixel, and a plurality of pixels arranged in a matrix constitute a pixel region. In the case where the LED chip 51 includes a plurality of light-emitting elements, the plurality of light-emitting elements serve as subpixels and one LED chip 51 serves as a pixel.

This embodiment shows, but is not particularly limited to, an example of using the extrusion mechanism 929; alternatively, LED chips may be mounted over the entire pixel region of the flexible substrate 800 with an apparatus for performing laser ablation by selective irradiation with laser light.

Then, the flexible substrate 800 over the entire pixel region of which the LED chips are mounted is fixed for adhesion to a support having a curved surface with the resin 19, whereby the display apparatus can be obtained.

In order to increase area, a plurality of substrates 800 are arranged to manufacture a display apparatus including pixel regions of m (m is a natural number of 2 or more) rows and n (n is a natural number of 1 or more) columns as one display surface.

The above is the description of the method for manufacturing a display apparatus.

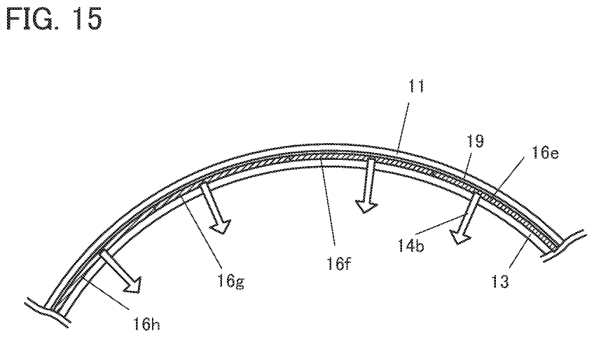

FIG. 5B illustrates, but is not particularly limited to, an example in which the light-emitting panels are provided on a convex surface side of the support 10 having a curved surface. FIG. 15 illustrates a modification example of the structure of FIG. 5B.

In the display apparatus of FIG. 15, a fifth light-emitting panel 16e, a sixth light-emitting panel 16f, a seventh light-emitting panel 16g, and an eighth light-emitting panel 16h are arranged and fixed to a concave surface side of a support 11. The fifth light-emitting panel 16e substantially corresponds to the first light-emitting panel although different reference numerals are used in order to avoid confusion with FIG. 5B. In the display apparatus illustrated in FIG. 15, a light-transmitting material is preferably used for the cover member 13. The support 11 has a curved surface. A light-emitting direction 14b of the fifth light-emitting panel 16e is different from the direction in FIG. 5B.

In the description of FIG. 5A, FIG. 5B, and FIG. 15, the support having a fixed radius of curvature is used, but without particular limitation, a whole display surface is not necessarily curved: part of the display surface may be flat or a display surface may have a convex shape and a concave shape in combination in accordance with a vehicle interior component (e.g., a dashboard, a ceiling, a pillar, window glass, a steering wheel, a seat, or an inner portion of a door). For example, the display apparatus of one embodiment of the present invention can be provided on the inner wall of a car, specifically, a dashboard, a ceiling, or a wall. The display apparatus of one embodiment of the present invention can have a display surface including a display region with a large area, and thus can be used as a navigation device for a means of transportation (an airplane or a submarine) without limited to a car because a map with a relatively large area can be displayed.

Furthermore, when the display surface is provided with a touch sensor, the display surface can be operated by touch of a driver's hand or finger. Therefore, the display apparatus including a touch sensor can also be referred to as an operating apparatus for vehicle.

A flexible substrate is more fragile than a glass substrate. In a portable information terminal where input operations are performed by touch or approach of a finger, especially in the case where a touch panel is mounted, a surface protective film is preferably provided so that dirt (sebum) or scratches from finger nails are prevented.

Also in a display apparatus provided in a vehicle, input operations are performed by touch or approach of a finger, it is thus preferable that a protective film having an excellent abrasion resistance be provided on the outermost surface of the display apparatus. As the protective film, a silicon oxide film having optically good characteristics (a high visible light transmittance or a high infrared light transmittance) is used. Providing the protective film can prevent damages and dirt in the film. The protective film may be formed using DLC (diamond like carbon), alumina (AlOₓ), a polyester-based material, or a polycarbonate-based material. Note that the protective film is preferably formed using a material that has a high hardness as well as high visible light transmittance.

In the case where the protective film is formed by a coating method, the protective film can be formed before a display apparatus is fixed to a support having a curved surface or can be formed after the display apparatus is fixed to the support having a curved surface.

As described above, with the structure of one embodiment of the present invention, a display apparatus with high display quality can be provided. Alternatively, with the structure of one embodiment of the present invention, flexibility in design of a display apparatus is improved and thus design of the display apparatus can be improved.

At least part of this embodiment can be implemented in appropriate combination with the other embodiments described in this specification.

### Embodiment 3

The structure of the LED chip 51 shown in Embodiment 2 is described in this embodiment. The LED chip 51 is also referred to as a light-emitting diode chip in some cases.

The LED chip includes a light-emitting diode. There is no particular limitation on the structure of the light-emitting diode; an MIS (Metal Insulator Semiconductor) junction may be used or a homostructure, a heterostructure, or a double-heterostructure having a PN junction or a PIN junction can be used. It is also possible to use a superlattice structure, or a single quantum well structure or a multi quantum well (MQW) structure where thin films producing a quantum effect are stacked. Alternatively, a nanocolumn LED chip may be used.

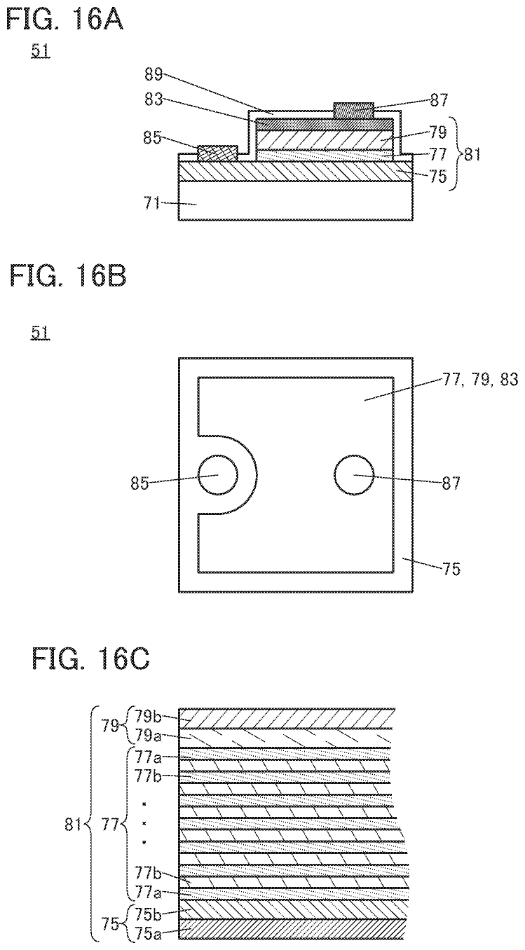

An example of the LED chip is illustrated in FIG. 16A and FIG. 16B. FIG. 16A shows a cross-sectional view of the LED chip 51 and FIG. 16B shows a top view of the LED chip 51. The LED chip 51 includes the semiconductor layer 81. The semiconductor layer 81 includes an n-type semiconductor layer 75, a light-emitting layer 77 over the n-type semiconductor layer 75, and a p-type semiconductor layer 79 over the light-emitting layer 77. A material that can be used for the p-type semiconductor layer 79 has a larger band gap energy than the light-emitting layer 77 and allows carriers to be trapped in the light-emitting layer 77. Also in the LED chip 51, the electrode 85 functioning as a cathode is provided over the n-type semiconductor layer 75, an electrode 83 functioning as a contact electrode is provided over the p-type semiconductor layer 79, and the electrode 87 functioning as an anode is provided over the electrode 83. In addition, a top surface and side surfaces of the electrode 83 are preferably covered with an insulating layer 89. The insulating layer 89 functions as a protective film of the LED chip 51.

An example of an enlarged view of the semiconductor layer 81 is illustrated in FIG. 16C. As illustrated in FIG. 16C, the n-type semiconductor layer 75 may include an n-type contact layer 75a on the substrate 71 side and an n-type clad layer 75b on the light-emitting layer 77 side. The p-type semiconductor layer 79 may include a p-type clad layer 79a on the light-emitting layer 77 side and a p-type contact layer 79b over the p-type clad layer 79a.

The light-emitting layer 77 can have a multiple quantum well (MQW) structure where a barrier layer 77a and a well layer 77b are stacked multiple times. The barrier layer 77a preferably uses a material having a larger band gap energy than the material for the well layer 77b. Such a structure allows the energy to be trapped in the well layer 77b, thereby improving the quantum efficiency and the emission efficiency of the LED chip 51.

In the LED chip 51 of a face-up type, a light-transmitting material can be used for the electrode 83; for example, an oxide such as ITO (In₂O₃—SnO₂), AZO (Al₂O₃—ZnO), In—Zn oxide (In₂O₃—ZnO), GZO (GeO₂—ZnO), or ICO (In₂O₃—CeO₂) can be used. In the LED chip 51 of a face-up type, light is mainly emitted to the electrode 87 side. In the LED chip 51 of a face-down type, a light-reflecting material can be used for the electrode 83; for example, silver, aluminum, or rhodium can be used. In the LED chip 51 of a face-down type, light is mainly emitted to the substrate 71 side.

For the substrate 71, oxide single crystal typified by sapphire single crystal (Al₂O₃), spinel single crystal (MgAl₂O₄), ZnO single crystal, LiAlO₂ single crystal, LiGaO₂ single crystal, and MgO single crystal, Si single crystal, SiC single crystal, GaAs single crystal, AIN single crystal, GaN single crystal, or boride single crystal typified by ZrB₂ can be used. In the LED chip 51 of a face-down type, a light-transmitting material is preferably used for the substrate 71; for example, sapphire single crystal that transmits light can be used.

A buffer layer (not illustrated) may be provided between the substrate 71 and the n-type semiconductor layer 75. The buffer layer has a function of alleviating the difference in lattice constant between the substrate 71 and the n-type semiconductor layer 75.

The LED chip 51 that can be used as the light-emitting diode chip 17 preferably has a horizontal structure where the electrode 85 and the electrode 87 are positioned on the same plane side as illustrated in FIG. 16A. When the electrode 85 and the electrode 87 are provided on the same plane side in the LED chip 51, the electrode 21 and the electrode 23 can be easily connected thereto and can each have a simple structure. The LED chip 51 that can be used as the light-emitting diode chip 17 is preferably of a face-down type. The use of the LED chip 51 of a face-down type allows light from the LED chip 51 to be efficiently emitted to the display surface side of the display apparatus, so that the display apparatus can have high luminance. A commercial LED chip may be used as the LED chip 51.

A phosphor layer is used in order to obtain white light emission. As a phosphor included in the phosphor layer, an organic resin layer having a surface on which a phosphor is printed or which is coated with a phosphor, or an organic resin layer mixed with a phosphor can be used. The phosphor layer can be formed using a material that is excited by light emitted from the LED chip 51 and emits light of a complementary color of the emission color of the LED chip 51. With such a structure, light emitted from the light-emitting diode chip 17 and light emitted from the phosphor are combined, so that the phosphor layer can emit white light.

For example, a structure where white light is emitted from the phosphor layer can be obtained with use of the LED chip 51 emitting blue light and a phosphor emitting yellow light, which is a complementary color of blue. The LED chip 51 that can emit blue light is typically a diode made of a Group 13 nitride-based compound semiconductor, e.g., a diode containing a GaN-based material which is represented by a formula, InₓAl_{y}Ga_{1-x-y}N (x is greater than or equal to 0) and less than or equal to 1, y is greater than or equal to 0 and less than or equal to 1, and x+y is greater than or equal to 0 and less than or equal to 1). Typical examples of the phosphor that is excited by blue light and emits yellow light include Y₃Al₅O₁₂:Ce (YAG:Ce) and (Ba,Sr,Mg)₂SiO₄:Eu,Mn.

For example, a structure where white light is emitted from the phosphor layer can be obtained with use of the LED chip 51 emitting blue-green light and a phosphor emitting red light, which is a complementary color of blue-green.

The phosphor layer may include a plurality of kinds of phosphors and each of the phosphors may emit light of a different color. For example, a structure where white light is emitted from the phosphor layer can be obtained with use of the LED chip 51 emitting blue light, a phosphor emitting red light, and a phosphor emitting green light. Typical examples of the phosphor that is excited by blue light and emits red light include (Ca,Sr)S:Eu and Sr₂Si₇Al₃ON₁₃:Eu. Typical examples of the phosphor that is excited by blue light and emits green light include SrGa₂S₄:Eu and Sr₃Si₁₃Al₃O₂N₂₁:Eu.

A structure where white light is emitted from the phosphor layer can be obtained with use of the LED chip 51 emitting near-ultraviolet light or violet light, a phosphor emitting red light, a phosphor emitting green light, and a phosphor emitting blue light. Typical examples of the phosphor that is excited by near-ultraviolet light or violet light and emits red light include (Ca, Sr)S:Eu, Sr₂Si₇Al₃ON₁₃:Eu, and La₂O₂S:Eu. Typical examples of the phosphor that is excited by near-ultraviolet light or violet light and emits green light include SrGa₂S₄:Eu and Sr₃Si₁₃Al₃O₂N₂₁:Eu. Typical examples of the phosphor that is excited by near-ultraviolet light or violet light and emits blue light include Sr₁₀(PO₄)₆Cl₂:Eu and (Sr,Ba,Ca)₁₀(PO₄)₆Cl₂:Eu.

Note that near-ultraviolet light has a maximum peak at a wavelength of 200 nm to 380 nm in an emission spectrum. Violet light has a maximum peak at a wavelength of 380 nm to 430 nm in an emission spectrum. Blue light has a maximum peak at a wavelength of 430 nm to 490 nm in an emission spectrum. Green light has a maximum peak at a wavelength of 490 nm to 550 nm in an emission spectrum. Yellow light has a maximum peak at a wavelength of 550 nm to 590 nm in an emission spectrum. Red light has a maximum peak at a wavelength of 640 nm to 770 nm in an emission spectrum.

In the case where the phosphor layer includes a phosphor emitting yellow light and the LED chip 51 emitting blue light is used, light emitted from the LED chip 51 preferably has a maximum peak at a wavelength of 330 nm to 500 nm in an emission spectrum, further preferably a maximum peak at a wavelength of 430 nm to 490 nm, and still further preferably a maximum peak at a wavelength of 450 nm to 480 nm. This allows efficient excitation of the phosphor. When light emitted from the LED chip 51 has a maximum peak at 430 nm to 490 nm in an emission spectrum, blue light that is excitation light and yellow light that is from the phosphor can be mixed to be white light. Furthermore, when light emitted from the LED chip 51 has a maximum peak at 450 nm to 480 nm, white with high purity can be obtained.

The above is the description of the structure example of the LED chip 51.

At least part of this embodiment can be implemented in appropriate combination with the other embodiments described in this specification.

### Embodiment 4

In this embodiment, examples of the display apparatus illustrated in Embodiment 1, Embodiment 2, or Embodiment 3 as an example will be described in detail.

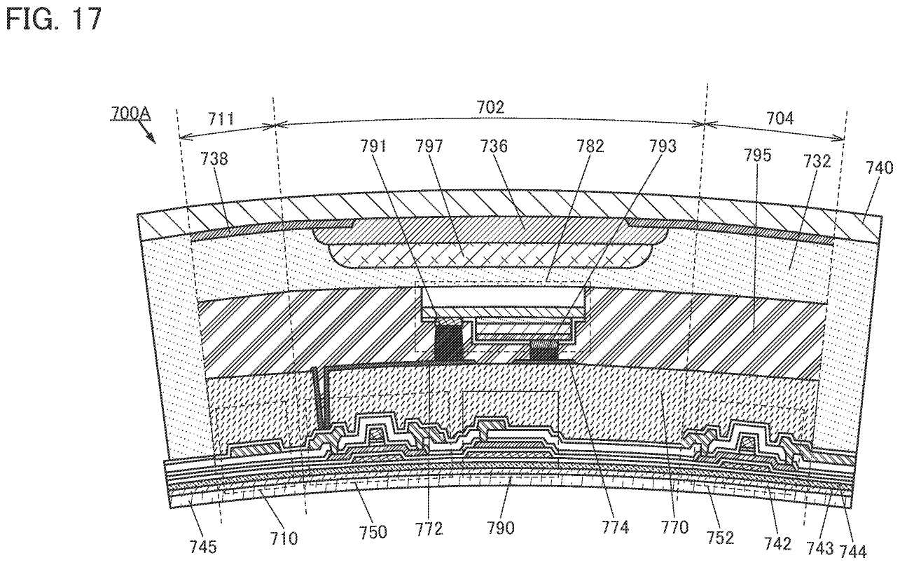

FIG. 17 illustrates an example of a cross-sectional view of a display apparatus 700A.

The display apparatus 700A includes a first substrate 745 and a second substrate 740 that are attached to each other with a resin 732.

The pixel region 702 is provided over the first substrate 745. A plurality of light-emitting elements 782 are provided in the pixel region 702.

There is no particular limitation on the structure of a transistor included in the pixel region 702. For a semiconductor layer of the transistor, a single crystal semiconductor, a polycrystalline semiconductor, a microcrystalline semiconductor, or an amorphous semiconductor can be used alone or in combination. As a semiconductor material, silicon or germanium can be used, for example. A compound semiconductor typified by silicon germanium, silicon carbide, gallium arsenide, an oxide semiconductor, or a nitride semiconductor, or an organic semiconductor can also be used.

In the case where an organic semiconductor is used for the semiconductor layer, a low molecular organic material having an aromatic ring, or a π-electron conjugated conductive high molecule can be used. For example, rubrene, tetracene, pentacene, perylenediimide, tetracyanoquinodimethane, polythiophene, polyacetylene, or polyparaphenylene vinylene can be used.

The transistor used in this embodiment preferably includes a highly purified oxide semiconductor film in which formation of oxygen vacancies is inhibited. Such a transistor can have a low off-state current. Hence, an electrical signal (an image signal) can be held for a longer time, and the interval between writings can also be set longer in a power on state. As a result, the frequency of refresh operations can be reduced, resulting in an effect of reducing power consumption.

The transistor using the oxide semiconductor film (also referred to as an OS transistor) can have relatively high field-effect mobility and thus is capable of high-speed operation. Moreover, when the transistors capable of high-speed operation are used also in the pixel portion, a high-quality image can be provided.

The transistor using the oxide semiconductor film can be formed by a known technique as appropriate. In FIG. 17, the transistor 750 can be considered as a type of top-gate transistor including a back gate electrode. The potential of the back gate electrode may be the same as the potential of the gate electrode or may be a ground potential (GND potential) or a given potential. In addition, when the potential of the back gate electrode is changed without synchronization and independently of the potential of the gate electrode, the threshold voltage of the transistor can be changed.

The gate electrode and the back gate electrode are formed using conductive layers and thus each have a function of preventing an electric field generated outside the transistor from influencing the semiconductor layer in which the channel is formed (in particular, an electric field blocking function against static electricity). Note that when the back gate electrode is formed larger than the semiconductor layer such that the semiconductor layer is covered with the back gate electrode, the electric field blocking function can be enhanced.

The display apparatus 700A illustrated in FIG. 17 includes a lead wiring portion 711, the pixel region 702, and the gate driver circuit portion 704. The lead wiring portion 711 includes a signal line 710. The pixel region 702 includes the transistor 750 and a capacitor 790. The gate driver circuit portion 704 includes a transistor 752. Although not illustrated, a source driver circuit portion including a transistor may be provided. The gate driver circuit portion 704 and the source driver circuit portion are not necessarily provided over the first substrate 745 and may be mounted as IC in another portion.

The capacitor 790 illustrated in FIG. 17 includes a lower electrode formed by processing a film used for the first gate electrode of the transistor 750 and an upper electrode formed by processing a metal oxide film used for the semiconductor layer. The resistance of the upper electrode is reduced as those of a source region and a drain region of the transistor 750. Part of an insulating film functioning as a first gate insulating layer of the transistor 750 is provided between the lower electrode and the upper electrode. That is, the capacitor 790 has a stacked-layer structure in which an insulating film functioning as a dielectric film is positioned between a pair of electrodes. A wiring obtained by processing a film used for a source electrode and a drain electrode of the transistor is connected to the upper electrode.

An insulating layer 770 is provided over the transistor 750, the transistor 752, and the capacitor 790. The insulating layer 770 functions as a planarization film, so that top surfaces of a conductive layer 772 and a conductive layer 774 provided over the insulating layer 770 can be made flat. The conductive layer 772 and the conductive layer 774 are positioned on the same plane and have the flat top surfaces, which facilitates electrical connection of the conductive layer 772 and the conductive layer 774 to the light-emitting element 782.

The conductive layer 772 and the conductive layer 774 are electrically connected to the light-emitting element 782 through a bump 791 and a bump 793 each having conductivity. FIG. 17 illustrates a structure in which a cathode-side electrode and an anode-side electrode of the light-emitting element 782 have different heights and the bump 791 and the bump 793 have different heights accordingly. Note that in the case where the cathode-side electrode and the anode-side electrode of the light-emitting element 782 have the same height, the bump 791 and the bump 793 can have substantially the same height.

As illustrated in FIG. 17, the transistor 750 included in the pixel region 702 is preferably provided under and overlapping with the conductive layer 772. When the transistor 750, particularly a channel formation region, has a region overlapping with the conductive layer 772, light emitted from the light-emitting element 782 and external light can be inhibited from reaching the transistor 750, so that a change in the electrical characteristics of the transistor 750 can be inhibited.

The transistor 750 included in the pixel region 702 and the transistor 752 included in the gate driver circuit portion 704 may have different structures. For example, a top-gate transistor may be used as one of the transistors and a bottom-gate transistor may be used as the other. Note that the same applies to the source driver circuit portion, as in the gate driver circuit portion 704.

The signal line 710 is formed using the same conductive film as the source electrodes and the drain electrodes of the transistors 750 and 752. In this case, a low-resistance material typified by a material containing a copper element is preferably used because signal delay due to the wiring resistance can be reduced and display on a large screen is possible.

Since a flexible substrate is used as the first substrate 745, an insulating layer having a barrier property against water or hydrogen is preferably provided between the first substrate 745 and the transistor 750. In addition, the first substrate 745, an adhesive layer 742, a resin layer 743, and an insulating layer 744 are stacked. The transistor 750 or the capacitor 790 is provided over the insulating layer 744 over the resin layer 743. The resin layer 743 and the first substrate 745 are bonded to each other with the adhesive layer 742. The resin layer 743 is preferably thinner than the first substrate 745.

The second substrate 740 is bonded to the resin 732. A resin film can be used as the second substrate 740. The second substrate 740 may include an optical member (e.g., a scattering plate), an input device typified by a touch sensor panel, or a stack including two or more of them.

On the second substrate 740 side, a light-blocking layer 738, a coloring layer 736, and a phosphor layer 797 are provided. The coloring layer 736 is provided over the light-emitting element 782. The phosphor layer 797 is provided between the light-emitting element 782 and the coloring layer 736. The phosphor layer 797, the light-emitting element 782, and the coloring layer 736 include a region in which they overlap with one another. It is preferable that, as illustrated in FIG. 17, end portions of the phosphor layer 797 be positioned on outer sides than end portions of the light-emitting element 782 and end portions of the coloring layer 736 be positioned on outer sides than end portions of the phosphor layer 797. With such a structure, light leakage to an adjacent pixel and mixture of colors between pixels can be inhibited. In addition, when the light-blocking layer 738 is provided between adjacent coloring layers 736, reflection of external light can be reduced to offer a display apparatus with a high contrast.

For example, when the phosphor layer 797 includes a phosphor emitting yellow light and the light-emitting element 782 emits blue light, white light is emitted from the phosphor layer 797. Light emitted from the light-emitting element 782 that is provided in a region overlapping with the coloring layer 736 transmitting red light passes through the phosphor layer 797 and the coloring layer 736 and is emitted to the display surface side as red light. In the same way, light emitted from the light-emitting element 782 that is provided in a region overlapping with the coloring layer 736 transmitting green light is emitted as green light. Light emitted from the light-emitting element 782 that is provided in a region overlapping with the coloring layer 736 transmitting blue light is emitted as blue light. As a result, color display can be performed with a type of light-emitting element 782. The display apparatus using one type of light-emitting element 782 can be fabricated in a simple process. That is, according to one embodiment of the present invention, a display apparatus with a high luminance, a high contrast, a high response speed, and low power consumption can be obtained at a low manufacturing cost

For example, a structure in which white light is emitted from the phosphor layer 797 can be obtained when the phosphor layer 797 includes a phosphor emitting red light and the light-emitting element 782 emits blue-green light.

Alternatively, a structure in which white light is emitted from the phosphor layer 797 can be obtained when the phosphor layer 797 includes a phosphor emitting red light, a phosphor emitting green light, and a phosphor emitting blue light and the light-emitting element 782 emits near-ultraviolet light or violet light.

The display apparatus 700A illustrated in FIG. 17 includes the light-emitting element 782. As the light-emitting element 782, the LED chip of a face-down type is preferably used.

The coloring layer 736 is provided to overlap with the light-emitting element 782, and the light-blocking layer 738 is provided in the lead wiring portion 711, the gate driver circuit portion 704, and a position overlapping with the end portions of the coloring layer 736. The space between the light-emitting element 782 and each of the phosphor layer 797, the coloring layer 736, and the light-blocking layer 738 is filled with the resin 732.

A resin layer 795 is provided so as to be adjacent to the light-emitting element 782. The resin layer 795 is preferably provided between adjacent light-emitting elements 782.

Note that thin films that form the display apparatus (insulating films, semiconductor films, and conductive films) can be formed by a sputtering method, a chemical vapor deposition (CVD) method, a vacuum evaporation method, a pulsed laser deposition (PLD) method, or an atomic layer deposition (ALD) method. As the CVD method, a plasma-enhanced chemical vapor deposition (PECVD) method or a thermal CVD method may be used. As an example of the thermal CVD method, a metal organic chemical vapor deposition (MOCVD) method may be used.

The thin films that form the display apparatus (insulating films, semiconductor films, and conductive films) can be formed by spin coating, dipping, spray coating, ink-jetting, dispensing, screen printing, or offset printing, or with a doctor knife, a slit coater, a roll coater, a curtain coater, or a knife coater.

When the thin films that form the display apparatus are processed, a photolithography method can be used for the processing. Alternatively, island-shaped thin films may be formed by a film formation method using a blocking mask. Alternatively, a nanoimprinting method, a sandblasting method, or a lift-off method may be used for the processing of the thin films. The following two examples of a photolithography method can be given. In one method, a photosensitive resist material is applied onto a thin film to be processed and exposed to light through a photomask; development is performed to form a resist mask; the thin film is processed by etching; then, the resist mask is removed. In the other method, after a photosensitive thin film is formed, light exposure and development are performed, so that the thin film is processed into a desired shape.

For light used for exposure in a photolithography method, for example, an i-line (with a wavelength of 365 nm), a g-line (with a wavelength of 436 nm), an h-line (with a wavelength of 405 nm), or combined light of any of them can be used. Besides, ultraviolet light, KrF laser light, or ArF laser light can be used. Light exposure may be performed by liquid immersion exposure technique. As the light used for the exposure, extreme ultra-violet (EUV) light or X-rays may be used. Instead of the light used for the exposure, an electron beam can also be used. It is preferable to use extreme ultra-violet light, X-rays, or an electron beam because extremely minute processing can be performed. Note that in the case of performing light exposure by scanning of an electron beam, a photomask is not needed.

For etching of the thin film, a dry etching method, a wet etching method, or a sandblast method can be used.

A plurality of aforementioned display apparatuses 700A are arranged side by side, so that a display apparatus including a display surface with a large area can be achieved. In addition, the aforementioned display apparatuses 700A are arranged side by side over a support having a curved surface, so that a display surface with a curved surface can be achieved.

At least part of this embodiment can be implemented in appropriate combination with the other embodiments described in this specification.

### Embodiment 5

In this embodiment, a metal oxide (also referred to as an oxide semiconductor) that can be used in the OS transistor described in Embodiment 4 will be described.

A metal oxide used in an OS transistor preferably contains at least indium or zinc, and further preferably contains indium and zinc. The metal oxide preferably contains indium, M (M is one or more of gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example. In particular, M is preferably one or more kinds selected from gallium, aluminum, yttrium, and tin, and M is further preferably gallium.

The metal oxide can be formed by a sputtering method, a chemical vapor deposition (CVD) method typified by a metal organic chemical vapor deposition (MOCVD) method, or an atomic layer deposition (ALD) method.

Hereinafter, an oxide containing indium (In), gallium (Ga), and zinc (Zn) is described as an example of the metal oxide. Note that an oxide containing indium (In), gallium (Ga), and zinc (Zn) may be referred to as an In—Ga—Zn oxide.

### Classification of Crystal Structure

Amorphous (including a completely amorphous), CAAC (c-axis-aligned crystalline), nc (nanocrystalline), CAC (cloud-aligned composite), single-crystal, and polycrystalline (poly crystal) structures can be given as examples of a crystal structure of an oxide semiconductor.

Note that the crystal structure of a film or a substrate can be evaluated with an X-ray diffraction (XRD) spectrum. For example, evaluation is possible using an XRD spectrum that is obtained by GIXD (Grazing-Incidence XRD) measurement. Note that a GIXD method is also referred to as a thin film method or a Seemann-Bohlin method. Hereinafter, an XRD spectrum obtained from GIXD measurement is simply referred to as an XRD spectrum in some cases.

For example, the XRD spectrum of a quartz glass substrate shows a peak with a substantially bilaterally symmetrical shape. On the other hand, the peak of the XRD spectrum of the In—Ga—Zn oxide film having a crystal structure has a bilaterally asymmetrical shape. The bilaterally asymmetrical peak of the XRD spectrum clearly shows the existence of crystal in the film or the substrate. In other words, the crystal structure of the film or the substrate cannot be regarded as an amorphous state unless it has a bilaterally symmetrical peak in the XRD spectrum.

In addition, the crystal structure of a film or a substrate can also be evaluated with a diffraction pattern obtained by a nanobeam electron diffraction method (NBED) (such a pattern is also referred to as a nanobeam electron diffraction pattern). For example, a halo pattern is observed in the diffraction pattern of the quartz glass substrate, which indicates that the quartz glass substrate is in an amorphous state. Furthermore, not a halo pattern but a spot-like pattern is observed in the diffraction pattern of the In—Ga—Zn oxide film formed at room temperature. Thus, it is presumed that the In—Ga—Zn oxide film formed at room temperature is in an intermediate state, which is neither a single crystal or polycrystalline state nor an amorphous state, and that it cannot be concluded that the In—Ga—Zn oxide film is in an amorphous state.

### Structure of Oxide Semiconductor

Note that oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### CAAC-OS

The CAAC-OS is an oxide semiconductor that has a plurality of crystal regions each of which has c-axis alignment in a particular direction. Note that the particular direction refers to the thickness direction of a CAAC-OS film, the normal direction of a surface where the CAAC-OS film is formed, or the normal direction of the surface of the CAAC-OS film. The crystal region refers to a region having a periodic atomic arrangement. Note that when an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the orientation of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one minute crystal, the maximum diameter of the crystal region is less than 10 nm. In the case where the crystal region is formed of a large number of minute crystals, the size of the crystal region may be approximately several tens of nanometers.

In the case of an In—Ga—Zn oxide, the CAAC-OS tends to have a layered crystal structure (also referred to as a layered structure) in which a layer containing indium (In) and oxygen (hereinafter, an In layer) and a layer containing gallium (Ga), zinc (Zn), and oxygen (hereinafter, a (Ga,Zn) layer) are stacked. Indium and gallium can be replaced with each other. Therefore, indium may be contained in the (Ga,Zn) layer. In addition, gallium may be contained in the In layer. Note that zinc may be contained in the In layer. Such a layer-shaped structure is observed as a lattice image in a high-resolution TEM (Transmission Electron Microscope) image, for example.

When the CAAC-OS film is subjected to structural analysis by out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind or composition of the metal element contained in the CAAC-OS.

For example, a plurality of bright spots are observed in the electron diffraction pattern of the CAAC-OS film. Note that one spot and another spot are observed point-symmetrically with a spot of an incident electron beam passing through a sample (also referred to as a direct spot) as a symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement or a heptagonal lattice arrangement is included in the distortion in some cases. Note that a clear crystal grain boundary (also referred to as grain boundary) cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, or an interatomic bond distance changed by substitution of a metal atom.

Note that a crystal structure in which a clear crystal grain boundary is observed is what is called polycrystal. It is highly probable that the grain boundary becomes a recombination center and traps carriers and thus decreases the on-state current and field-effect mobility of a transistor. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a crystal grain boundary as compared with an In oxide.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor might be decreased by entry of impurities or formation of defects, the CAAC-OS can be regarded as an oxide semiconductor that has small amounts of impurities and defects (oxygen vacancies). Thus, an oxide semiconductor including the CAAC-OS is physically stable. Therefore, the oxide semiconductor including the CAAC-OS is resistant to heat and has high reliability. In addition, the CAAC-OS is stable with respect to high temperatures in the manufacturing process (what is called thermal budget). Accordingly, the use of the CAAC-OS for the OS transistor can extend the degree of freedom of the manufacturing process.

### nc-OS

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal. Note that the size of the minute crystal is, for example, greater than or equal to 1 nm and less than or equal to 10 nm, particularly greater than or equal to 1 nm and less than or equal to 3 nm; thus, the minute crystal is also referred to as a nanocrystal. Furthermore, there is no regularity of crystal orientation between different nanocrystals in the nc-OS. Thus, the orientation in the whole film is not observed. Accordingly, in some cases, the nc-OS cannot be distinguished from an a-like OS or an amorphous oxide semiconductor, depending on the analysis method. For example, when an nc-OS film is subjected to structural analysis by out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or smaller than the diameter of a nanocrystal (e.g., larger or equal to 1 nm and smaller than or equal to 30 nm).

### a-Like OS

The a-like OS is an oxide semiconductor having a structure between those of the nc-OS and the amorphous oxide semiconductor. The a-like OS contains a void or a low-density region. That is, the a-like OS has lower crystallinity than the nc-OS and the CAAC-OS. Moreover, the a-like OS has a higher hydrogen concentration in the film than the nc-OS and the CAAC-OS.

### Structure of Oxide Semiconductor

Next, the above-described CAC-OS will be described in detail. Note that the CAC-OS relates to the material composition.

### CAC-OS

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratios of In, Ga, and Zn to the metal elements contained in the CAC-OS in an In—Ga—Zn oxide are denoted by [In], [Ga], and [Zn], respectively. For example, the first region in the CAC-OS in the In—Ga—Zn oxide is a region having [In] higher than [In] in the composition of the CAC-OS film. Moreover, the second region is a region having [Ga] higher than [Ga] in the composition of the CAC-OS film. Alternatively, for example, the first region has higher [In] and lower [Ga] than the second region. Moreover, the second region is a region having [Ga] higher than [Ga] in the first region and [In] lower than [In] in the first region.

Specifically, the first region includes indium oxide or indium zinc oxide as its main component. The second region includes gallium oxide or gallium zinc oxide as its main component. That is, the first region can be rephrased as a region containing In as its main component. The second region can be rephrased as a region containing Ga as its main component.

Note that a clear boundary between the first region and the second region cannot be observed in some cases.

In a material composition of a CAC-OS in an In—Ga—Zn oxide that contains In, Ga, Zn, and O, there are regions containing Ga as a main component in part of the CAC-OS and regions containing In as a main component in another part of the CAC-OS. These regions each form a mosaic pattern and are randomly present. Thus, it is suggested that the CAC-OS has a structure in which metal elements are unevenly distributed.

The CAC-OS can be formed by a sputtering method under a condition where a substrate is intentionally not heated, for example. Furthermore, in the case where the CAC-OS is formed by a sputtering method, any one or more selected from an inert gas (typically, argon), an oxygen gas, and a nitrogen gas is used as a deposition gas. The ratio of the flow rate of an oxygen gas to the total flow rate of the deposition gas during deposition is preferably as low as possible. For example, the flow-rate proportion of an oxygen gas in the total deposition gas is preferably higher than or equal to 0% and lower than 30%, further preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

Here, the first region has higher conductivity than the second region. In other words, when carriers flow through the first region, the conductivity of a metal oxide is exhibited. Accordingly, when the first regions are distributed in a metal oxide like a cloud, high field-effect mobility (μ) can be achieved.

The second region has a higher insulating property than the first region. In other words, when the second regions are distributed in a metal oxide, leakage current can be inhibited.

Thus, in the case where a CAC-OS is used for a transistor, by the complementary action of the conductivity due to the first region and the insulating property due to the second region, the CAC-OS can have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Iₒₙ), high field-effect mobility (μ), and excellent switching operation can be achieved.

A transistor using the CAC-OS has high reliability. Thus, the CAC-OS is most suitable for a variety of semiconductor devices typified by display apparatuses.

An oxide semiconductor has various structures with different properties. Two or more kinds among an amorphous oxide semiconductor, a polycrystalline oxide semiconductor, an a-like OS, a CAC-OS, an nc-OS, and a CAAC-OS may be included in an oxide semiconductor of one embodiment of the present invention.

### Transistor Containing Oxide Semiconductor

Next, the case where the above oxide semiconductor is used for a transistor will be described.

When the above oxide semiconductor is used for a transistor, a transistor with high field-effect mobility can be achieved. In addition, a transistor having high reliability can be achieved.

An oxide semiconductor having a low carrier concentration is preferably used in a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification, a state with a low impurity concentration and a low density of defect states is referred to as a highly purified intrinsic or substantially highly purified intrinsic state. Note that an oxide semiconductor having a low carrier concentration is sometimes referred to as a highly purified intrinsic or substantially highly purified intrinsic oxide semiconductor.

A highly purified intrinsic or substantially highly purified intrinsic oxide semiconductor film has a low density of defect states and thus also has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon. Note that an impurity in an oxide semiconductor refers to, for example, elements other than the main components of the oxide semiconductor. For example, an element with a concentration lower than 0.1 atomic % can be regarded as an impurity.

### Impurity

Here, the influence of each impurity in the oxide semiconductor will be described.

When silicon or carbon, which is a Group 14 element, is contained in an oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) are each set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the oxide semiconductor, which is obtained by SIMS, is set lower than or equal to 1×10¹⁸ atoms/cm³, preferably lower than or equal to 2×10¹⁶ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor containing nitrogen as a semiconductor is likely to have normally-on characteristics. Alternatively, when nitrogen is contained in the oxide semiconductor, a trap state is sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor containing hydrogen is likely to have normally-on characteristics. For this reason, hydrogen in the oxide semiconductor is preferably reduced as much as possible. Specifically, the concentration of hydrogen in the oxide semiconductor, which is measured by SIMS, is lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, stable electrical characteristics can be given.

At least part of this embodiment can be implemented in combination with the other embodiments described in this specification as appropriate.

### Embodiment 6

In this embodiment, a structure example of a transistor that can be used in the display apparatus of one embodiment of the present invention will be described. Specifically, the case of using a transistor containing silicon in a semiconductor layer where a channel is formed will be described.

One embodiment of the present invention is a display apparatus including a light-emitting device and a pixel circuit. For example, three kinds of light-emitting devices emitting light of red (R), green (G), and blue (B) are included, whereby a full-color display apparatus can be achieved.

Transistors containing silicon in their semiconductor layers where channels are formed are preferably used as all transistors included in the pixel circuit for driving the light-emitting device. As silicon, single crystal silicon, polycrystalline silicon, and amorphous silicon can be given. In particular, a transistor containing low-temperature polysilicon (LTPS) in its semiconductor layer (hereinafter also referred to as an LTPS transistor) is preferably used. The LTPS transistor has high field-effect mobility and favorable frequency characteristics.

With the use of transistors containing silicon, typified by LTPS transistors, a circuit required to be driven at a high frequency (e.g., a source driver circuit) can be formed on the same substrate as the display portion. Thus, external circuits mounted on the display apparatus can be simplified, whereby parts costs and mounting costs can be reduced.

It is preferable to use transistors including a metal oxide (hereinafter also referred to as an oxide semiconductor) in their semiconductors where channels are formed (such transistors are hereinafter also referred to as OS transistors) as at least one of the transistors included in the pixel circuit. An OS transistor has extremely higher field-effect mobility than a transistor using amorphous silicon. In addition, the OS transistor has an extremely low leakage current between a source and a drain in an off state (hereinafter, also referred to as off-state current), and charge accumulated in a capacitor that is connected in series to the transistor can be retained for a long period. Furthermore, the power consumption of the display apparatus can be reduced with the use of an OS transistor.

When an LTPS transistor is used as one or more of the transistors included in the pixel circuit and an OS transistor is used as the rest, a display apparatus with low power consumption and high driving capability can be achieved. As a more preferable example, it is preferable to use an OS transistor as a transistor functioning as a switch for controlling electrical continuity between wirings and an LTPS transistor as a transistor for controlling current.

For example, one of the transistors included in the pixel circuit functions as a transistor for controlling current flowing through the light-emitting device and can be referred to as a driving transistor. One of a source and a drain of the driving transistor is electrically connected to the pixel electrode of the light-emitting device. An LTPS transistor is preferably used as the driving transistor. In this case, the amount of current flowing through the light-emitting device can be increased in the pixel circuit.

Another transistor included in the pixel circuit functions as a switch for controlling selection and non-selection of the pixel and can be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., 1 fps or less); thus, power consumption can be reduced by stopping the driver circuit in displaying a still image.

More specific structure examples are described below with reference to drawings.

### Structure Example of Display Apparatus

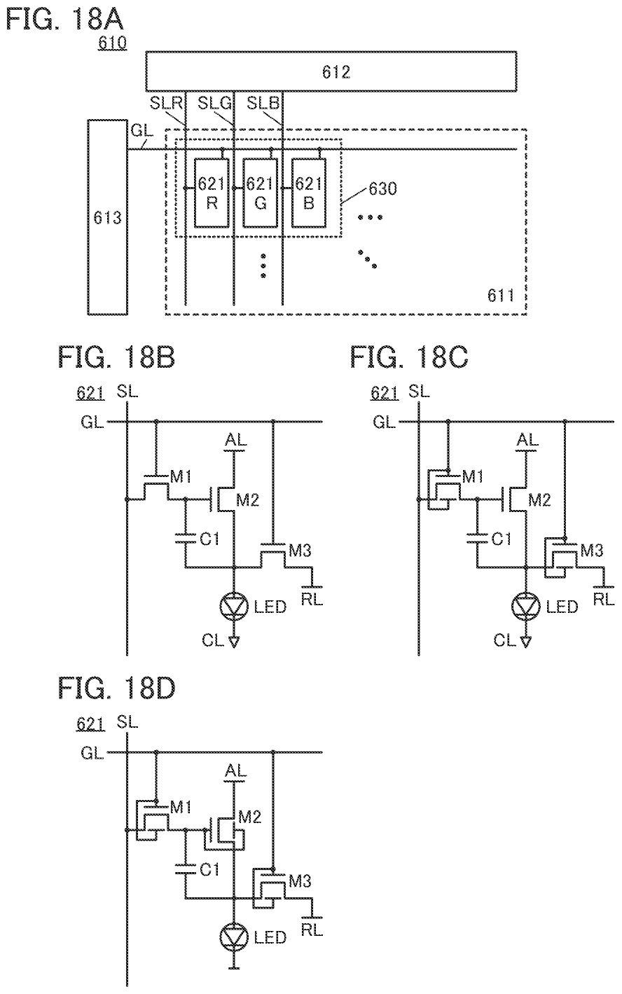

FIG. 18A illustrates a block diagram of a display apparatus 610. The display apparatus 610 includes a display portion 611, a driver circuit portion 612, and a driver circuit portion 613.

The display portion 611 includes a plurality of pixels 630 arranged in a matrix. The pixels 630 each include a subpixel 621R, a subpixel 621G, and a subpixel 621B. The subpixel 621R, the subpixel 621G, and the subpixel 621B each include a light-emitting device functioning as a display device.

The pixel 630 is electrically connected to a wiring GL, a wiring SLR, a wiring SLG, and a wiring SLB. The wiring SLR, the wiring SLG, and the wiring SLB are electrically connected to the driver circuit portion 612. The wiring GL is electrically connected to the driver circuit portion 613. The driver circuit portion 612 functions as a source line driver circuit (also referred to as a source driver), and the driver circuit portion 613 functions as a gate line driver circuit (also referred to as a gate driver). The wiring GL functions as a gate line, and the wiring SLR, the wiring SLG, and the wiring SLB each function as a source line.

The subpixel 621R includes a light-emitting device emitting red light. The subpixel 621G includes a light-emitting device emitting green light. The subpixel 621B includes a light-emitting device emitting blue light. Thus, the display apparatus 610 can perform full-color display. Note that the pixel 630 may include a subpixel including a light-emitting device emitting light of another color. For example, the pixel 630 may include, in addition to the three subpixels, a subpixel including a light-emitting device emitting white light, or a subpixel including a light-emitting device emitting yellow light.

The wiring GL is electrically connected to the subpixel 621R, the subpixel 621G, and the subpixel 621B arranged in a row direction (an extending direction of the wiring GL). The wiring SLR, the wiring SLG, and the wiring SLB are electrically connected to the subpixels 621R, the subpixels 621G, and the subpixels 621B (not illustrated) arranged in a column direction (an extending direction of the wiring SLR), respectively.

### Structure Example of Pixel Circuit

FIG. 18B illustrates an example of a circuit diagram of a pixel 621 that can be used as the subpixel 621R, the subpixel 621G, and the subpixel 621B. The pixel 621 includes a transistor M1, a transistor M2, a transistor M3, a capacitor C1, and a light-emitting device LED. The wiring GL and a wiring SL are electrically connected to the pixel 621. The wiring SL corresponds to any of the wiring SLR, the wiring SLG, and the wiring SLB illustrated in FIG. 18A.

A gate of the transistor M1 is electrically connected to the wiring GL, one of a source and a drain of the transistor M1 is electrically connected to the wiring SL, and the other thereof is electrically connected to one electrode of the capacitor C1 and a gate of the transistor M2. One of a source and a drain of the transistor M2 is electrically connected to a wiring AL, and the other of the source and the drain of the transistor M2 is electrically connected to one electrode of the light-emitting device LED, the other electrode of the capacitor C1, and one of a source and a drain of the transistor M3. A gate of the transistor M3 is electrically connected to the wiring GL, and the other of the source and the drain of the transistor M3 is electrically connected to a wiring RL. The other electrode of the light-emitting device LED is electrically connected to a wiring CL.

A data potential D is supplied to the wiring SL. A selection signal is supplied to the wiring GL. The selection signal includes a potential for bringing a transistor into a conducting state and a potential for bringing a transistor into a non-conducting state.

A reset potential is supplied to the wiring RL. An anode potential is supplied to the wiring AL. A cathode potential is supplied to the wiring CL. In the pixel 621, the anode potential is a potential higher than the cathode potential. The reset potential supplied to the wiring RL can be set such that a potential difference between the reset potential and the cathode potential is lower than the threshold voltage of the light-emitting device LED. The reset potential can be a potential higher than the cathode potential, a potential equal to the cathode potential, or a potential lower than the cathode potential.

The transistor M1 and the transistor M3 each function as a switch. The transistor M2 functions as a transistor for controlling current flowing through the light-emitting device LED. For example, it can be said that the transistor M1 functions as a selection transistor and the transistor M2 functions as a driving transistor.

Here, it is preferable to use LTPS transistors as all of the transistor M1 to the transistor M3. Alternatively, it is preferable to use OS transistors as the transistor M1 and the transistor M3 and to use an LTPS transistor as the transistor M2.

Alternatively, OS transistors may be used as all of the transistor M1 to the transistor M3. In this case, an LTPS transistor can be used as at least one of a plurality of transistors included in the driver circuit portion 612 and a plurality of transistors included in the driver circuit portion 613, and OS transistors can be used as the other transistors. For example, OS transistors can be used as the transistors provided in the display portion 611, and LTPS transistors can be used as the transistors provided in the driver circuit portion 612 and the driver circuit portion 613.

As the OS transistor, a transistor including an oxide semiconductor in its semiconductor layer where a channel is formed can be used. The semiconductor layer preferably contains indium, M (M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more selected from aluminum, gallium, yttrium, and tin. It is particularly preferable to use an oxide containing indium, gallium, and zinc (also referred to as IGZO) for the semiconductor layer of the OS transistor. Alternatively, it is preferable to use an oxide containing indium, tin, and zinc. Further alternatively, it is preferable to use an oxide containing indium, gallium, tin, and zinc.

A transistor using an oxide semiconductor having a wider band gap and a lower carrier density than silicon can achieve an extremely low off-state current. Thus, such a low off-state current enables long-term retention of charge accumulated in a capacitor that is connected to the transistor in series. Therefore, it is particularly preferable to use a transistor including an oxide semiconductor as the transistor M1 and the transistor M3 each of which is connected to the capacitor C1 in series. The use of the transistor including an oxide semiconductor as each of the transistor M1 and the transistor M3 can prevent leakage of charge retained in the capacitor C1 through the transistor M1 or the transistor M3. Furthermore, since charge retained in the capacitor C1 can be retained for a long time, a still image can be displayed for a long time without rewriting data in the pixel 621.

Note that although the transistor is illustrated as an n-channel transistor in FIG. 18B, a p-channel transistor can also be used.

The transistors included in the pixel 621 are preferably formed to be arranged over the same substrate.

Note that transistors each including a pair of gates overlapping with each other with a semiconductor layer therebetween can be used as the transistors included in the pixel 621.

In the transistor including a pair of gates, the same potential is supplied to the pair of gates electrically connected to each other, which brings advantage that the transistor can have a higher on-state current and improved saturation characteristics. A potential for controlling the threshold voltage of the transistor may be supplied to one of the pair of gates. Furthermore, when a constant potential is supplied to one of the pair of gates, the stability of the electrical characteristics of the transistor can be improved. For example, one of the gates of the transistor may be electrically connected to a wiring to which a constant potential is supplied or may be electrically connected to a source or a drain of the transistor.

The pixel 621 illustrated in FIG. 18C is an example in which a transistor including a pair of gates is used as each of the transistor M1 and the transistor M3. The pair of gates of each of the transistor M1 and the transistor M3 are electrically connected each other. Such a structure can shorten the period in which data is written to the pixel 621.

The pixel 621 illustrated in FIG. 18D is an example in which a transistor including a pair of gates is used as the transistor M2 in addition to the transistor M1 and the transistor M3. A pair of gates of the transistor M2 are electrically connected to each other. When such a transistor is used as the transistor M2, the saturation characteristics are improved, whereby emission luminance of the light-emitting device LED can be controlled easily and the display quality can be increased.

### Structure Example of Transistor

Cross-sectional structure examples of a transistor that can be used in the aforementioned display apparatus are described below.

### Structure Example 1

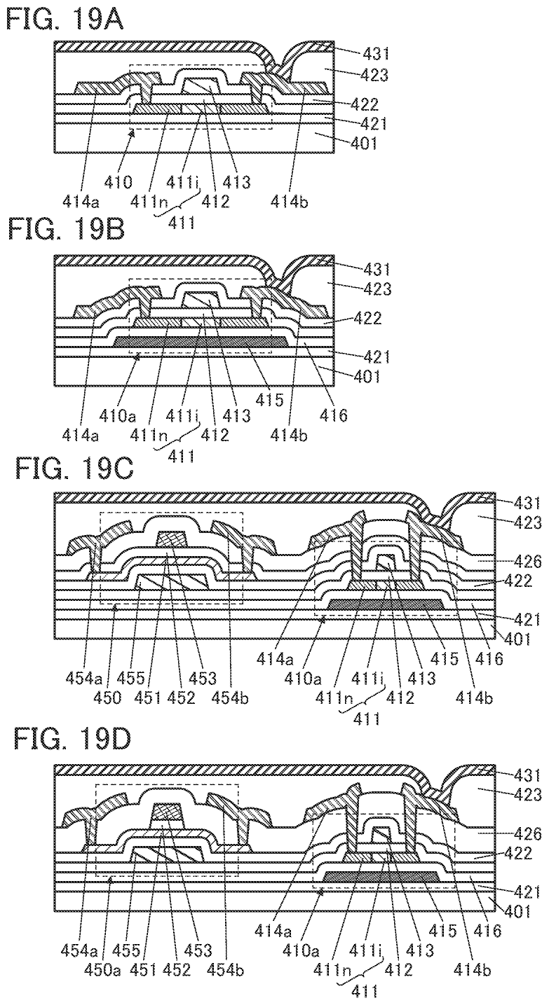

FIG. 19A is a cross-sectional view including a transistor 410.

The transistor 410 is provided over a substrate 401 and contains polycrystalline silicon in its semiconductor layer. For example, the transistor 410 corresponds to the transistor M2 in the pixel 621. In other words, FIG. 19A illustrates an example in which one of a source and a drain of the transistor 410 is electrically connected to a conductive layer 431 of the light-emitting device.

The transistor 410 includes a semiconductor layer 411, an insulating layer 412, and a conductive layer 413. The semiconductor layer 411 includes a channel formation region 411i and low-resistance regions 411n. The semiconductor layer 411 contains silicon. The semiconductor layer 411 preferably contains polycrystalline silicon. Part of the insulating layer 412 functions as a gate insulating layer. Part of the conductive layer 413 functions as a gate electrode.

Note that the semiconductor layer 411 can include a metal oxide exhibiting semiconductor characteristics (also referred to as an oxide semiconductor). In this case, the transistor 410 can be referred to as an OS transistor.

The low-resistance regions 411n are each a region containing an impurity element. For example, in the case where the transistor 410 is an n-channel transistor, phosphorus or arsenic is added to the low-resistance regions 411n. Meanwhile, in the case where the transistor 410 is a p-channel transistor, boron or aluminum is added to the low-resistance regions 411n. In addition, in order to control the threshold voltage of the transistor 410, the above-described impurity may be added to the channel formation region 411i.

An insulating layer 421 is provided over the substrate 401. The semiconductor layer 411 is provided over the insulating layer 421. The insulating layer 412 is provided to cover the semiconductor layer 411 and the insulating layer 421. The conductive layer 413 is provided at a position that is over the insulating layer 412 and overlaps with the semiconductor layer 411.

An insulating layer 422 is provided to cover the conductive layer 413 and the insulating layer 412. A conductive layer 414a and a conductive layer 414b are provided over the insulating layer 422. The conductive layer 414a and the conductive layer 414b are electrically connected to the low-resistance regions 411n in opening portions provided in the insulating layer 422 and the insulating layer 412. Part of the conductive layer 414a functions as one of a source electrode and a drain electrode and part of the conductive layer 414b functions as the other of the source electrode and the drain electrode. An insulating layer 423 is provided to cover the conductive layer 414a, the conductive layer 414b, and the insulating layer 422.

The conductive layer 431 functioning as a pixel electrode is provided over the insulating layer 423. The conductive layer 431 is provided over the insulating layer 423 and is electrically connected to the conductive layer 414b through an opening provided in the insulating layer 423. Although not illustrated here, an LED terminal can be mounted over the conductive layer 431.

### Structure Example 2

FIG. 19B illustrates a transistor 410a including a pair of gate electrodes. The transistor 410a illustrated in FIG. 19B is different from that in FIG. 19A mainly in including a conductive layer 415 and an insulating layer 416.

The conductive layer 415 is provided over the insulating layer 421. The insulating layer 416 is provided to cover the conductive layer 415 and the insulating layer 421. The semiconductor layer 411 is provided such that at least the channel formation region 411i overlaps with the conductive layer 415 with the insulating layer 416 therebetween.

In the transistor 410a illustrated in FIG. 19B, part of the conductive layer 413 functions as a first gate electrode, and part of the conductive layer 415 functions as a second gate electrode. At this time, part of the insulating layer 412 functions as a first gate insulating layer, and part of the insulating layer 416 functions as a second gate insulating layer.

Here, to electrically connect the first gate electrode to the second gate electrode, the conductive layer 413 may be electrically connected to the conductive layer 415 through an opening portion provided in the insulating layer 412 and the insulating layer 416 in a region not illustrated. To electrically connect the second gate electrode to a source or a drain, the conductive layer 415 may be electrically connected to the conductive layer 414a or the conductive layer 414b through an opening portion provided in the insulating layer 422, the insulating layer 412, and the insulating layer 416 in a region not illustrated.

In the case where LTPS transistors are used as all of the transistors included in the pixel 621, the transistor 410 illustrated in FIG. 19A as an example or the transistor 410a illustrated in FIG. 19B as an example can be used. In this case, the transistors 410a may be used as all of the transistors included in the pixels 621, the transistors 410 may be used as all of the transistors, or the transistors 410a and the transistors 410 may be used in combination.

### Structure Example 3

Described below is an example of a structure including both a transistor containing silicon in its semiconductor layer and a transistor containing a metal oxide in its semiconductor laver.

FIG. 19C is a schematic cross-sectional view including the transistor 410a and a transistor 450.

Structure example 1 described above can be referred to for the transistor 410a. Although an example of using the transistor 410a is illustrated here, a structure including the transistor 410 and the transistor 450 or a structure including all of the transistor 410, the transistor 410a, and the transistor 450 may be employed.

The transistor 450 is a transistor including a metal oxide in its semiconductor layer. The structure in FIG. 19C illustrates an example in which the transistor 450 corresponds to the transistor M1 in the pixel 621 and the transistor 410a corresponds to the transistor M2. That is, FIG. 19C illustrates an example in which one of a source and a drain of the transistor 410a is electrically connected to the conductive layer 431.

Moreover, FIG. 19C illustrates an example in which the transistor 450 includes a pair of gates.

The transistor 450 includes a conductive layer 455, the insulating layer 422, a semiconductor layer 451, an insulating layer 452, and a conductive layer 453. Part of the conductive layer 453 functions as a first gate of the transistor 450, and part of the conductive layer 455 functions as a second gate of the transistor 450. In this case, part of the insulating layer 452 functions as a first gate insulating layer of the transistor 450, and part of the insulating layer 422 functions as a second gate insulating layer of the transistor 450.

The conductive layer 455 is provided over the insulating layer 412. The insulating layer 422 is provided to cover the conductive layer 455. The semiconductor layer 451 is provided over the insulating layer 422. The insulating layer 452 is provided to cover the semiconductor layer 451 and the insulating layer 422. The conductive layer 453 is provided over the insulating layer 452 and includes a region overlapping with the semiconductor layer 451 and the conductive layer 455.

An insulating layer 426 is provided to cover the insulating layer 452 and the conductive layer 453. A conductive layer 454a and a conductive layer 454b are provided over the insulating layer 426. The conductive layer 454a and the conductive layer 454b are electrically connected to the semiconductor layer 451 in opening portions provided in the insulating layer 426 and the insulating layer 452. Part of the conductive layer 454a functions as one of a source electrode and a drain electrode and part of the conductive layer 454b functions as the other of the source electrode and the drain electrode. The insulating layer 423 is provided to cover the conductive layer 454a, the conductive layer 454b, and the insulating layer 426.

Here, the conductive layer 414a and the conductive layer 414b electrically connected to the transistor 410a are preferably formed by processing the same conductive film as the conductive layer 454a and the conductive layer 454b. In FIG. 19C, the conductive layer 414a, the conductive layer 414b, the conductive layer 454a, and the conductive layer 454b are formed on the same plane (i.e., in contact with the top surface of the insulating layer 426) and contain the same metal element. In this case, the conductive layer 414a and the conductive layer 414b are electrically connected to the low-resistance regions 411n through openings provided in the insulating layer 426, the insulating layer 452, the insulating layer 422, and the insulating layer 412. This is preferable because the manufacturing process can be simplified.

Moreover, the conductive layer 413 functioning as the first gate electrode of the transistor 410a and the conductive layer 455 functioning as the second gate electrode of the transistor 450 are preferably formed by processing the same conductive film. FIG. 19C illustrates a structure where the conductive layer 413 and the conductive layer 455 are formed on the same plane (i.e., in contact with the top surface of the insulating layer 412) and contain the same metal element. This is preferable because the manufacturing process can be simplified.

In the structure in FIG. 19C, the insulating layer 452 functioning as the first gate insulating layer of the transistor 450 covers an end portion of the semiconductor layer 451; however, the insulating layer 452 may be processed to have the same or substantially the same top surface shape as the conductive layer 453 as in the transistor 450a illustrated in FIG. 19D.

Note that in this specification, the expression “top surface shapes are substantially the same” means that at least outlines of stacked layers partly overlap with each other. For example, the case of processing the upper layer and the lower layer with the use of the same mask pattern or mask patterns that are partly the same is included. However, in some cases, the outlines do not completely overlap with each other and the upper layer is positioned inward from the lower layer or the upper layer is positioned outward from the lower layer; such cases are also represented by the expression “top surface shapes are substantially the same”.

Although the example in which the transistor 410a corresponds to the transistor M2 and is electrically connected to the pixel electrode is shown here, one embodiment of the present invention is not limited thereto. For example, a structure in which the transistor 450 or the transistor 450a corresponds to the transistor M2 may be employed. In that case, the transistor 410a corresponds to the transistor M1, the transistor M3, or another transistor.

This embodiment can be combined with the other embodiments as appropriate.

### Embodiment 7

This embodiment relates to a display apparatus in which subpixels are provided in a matrix and each include a light-emitting element (a light-emitting diode chip).

The display apparatus of one embodiment of the present invention has a structure in which light-emitting diode chips are separately mounted over subpixels with different colors. In the display apparatus of one embodiment of the present invention, a plurality of subpixels emitting light of the same color are arranged adjacent to each other both in the row direction and in the column direction. In other words, the plurality of subpixels emitting light of the same color are separated independently.

In this specification, two subpixels that have the same coordinate in the row direction but coordinates in the column direction different from each other by one are referred to as subpixels adjacent in the row direction. For example, a subpixel in the first row and the second column is adjacent, in the row direction, to a subpixel in the first row and the first column. Two subpixels that have the same coordinate in the column direction but coordinates in the row direction different from each other by one are referred to as subpixels adjacent in the column direction. For example, a subpixel in the second row and the first column is adjacent, in the column direction, to the subpixel in the first row and the first column. The same expression is also applied to components, other than subpixels, as long as they are arranged in a matrix. For example, in the case where a plurality of subpixels emitting light of the same color are divided into four, they may be divided into two in the row direction and divided into two in the column direction.

### Structure Example of Display Apparatus

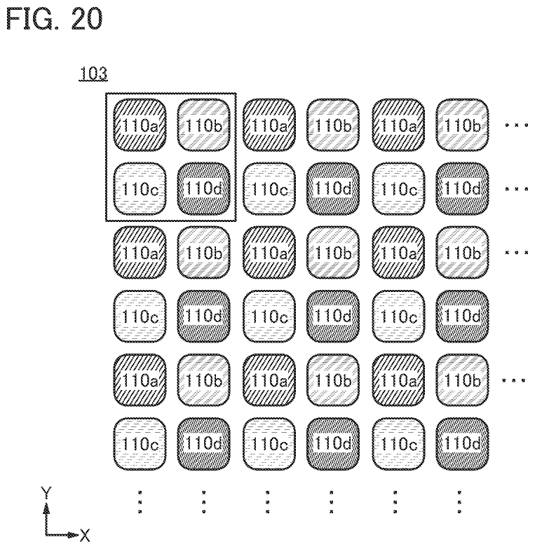

FIG. 20 is a top view illustrating a structure example of a pixel 103 in the display apparatus of one embodiment of the present invention.

The pixel 103 illustrated in FIG. 20 is composed of four subpixels: a subpixel 110a, a subpixel 110b, a subpixel 110c, and a subpixel 110d. The subpixel 110a, the subpixel 110b, the subpixel 110c, and the subpixel 110d include light-emitting elements emitting light of different colors. The subpixel 110a, the subpixel 110b, and the subpixel 110c can be subpixels of four colors of red (R), green (G), blue (B), and white (W). The subpixel 110a illustrated in FIG. 20 is formed so as to correspond to one LED chip, whereby the LED chip with two terminals can be mounted. A plurality of subpixels may be provided in one chip in order to simplify the mounting process. For example, subpixels of three colors of red (R), green (G), and blue (B) may be provided in one chip and the LED chip with four terminals may obtained. Note that FIG. 20 illustrates an example in which one chip is composed of subpixels of four colors surrounded by a rectangle and the chips are arranged in a matrix. A chip composed of subpixels of four colors includes five terminals. Although the subpixels have the same area in FIG. 20, one embodiment of the present invention is not particularly limited thereto and for example, in the case where subpixels of three colors are used, only a subpixel of green may have a larger area than the other subpixels.

In this specification, for example, matters common to the subpixel 110a, the subpixel 110b, the subpixel 110c, and the subpixel 110d are described in some cases. As for other components that are distinguished from each other using letters of the alphabet, matters common to the components are sometimes described using reference numerals excluding the letters of the alphabet.

FIG. 20 illustrates the subpixel in the first row and the first column to the subpixel in the sixth row and the sixth column.

In this specification, the row direction is referred to as X direction and the column direction is referred to as Y direction. The X direction and the Y direction intersect with each other and are perpendicular to each other, for example.

This embodiment can be freely combined with the other embodiments.

### Embodiment 8

In this embodiment, an example of a display apparatus of one embodiment of the present invention will be described.

In the display apparatus of this embodiment, a pixel can include a plurality of types of subpixels including light-emitting devices that emit light of different colors. For example, the pixel can include three kinds of subpixels. As the three subpixels, subpixels of three colors of red (R), green (G), and blue (B) and subpixels of three colors of yellow (Y), cyan (C), and magenta (M) can be given. Alternatively, the pixel can include four kinds of subpixels. As the four subpixels, subpixels of four colors of R, G, B, and white (W) and subpixels of four colors of R, G, B, and Y can be given.

There is no particular limitation on the arrangement of subpixels, and a variety of methods can be employed. Examples of the arrangement of subpixels include stripe arrangement, S-stripe arrangement, matrix arrangement, delta arrangement, Bayer arrangement, and PenTile arrangement.

Examples of a top surface shape of the subpixel include polygons typified by a triangle, a tetragon (including a rectangle and a square), and a pentagon; polygons with rounded corners; an ellipse; and a circle. The top surface shape of a subpixel herein refers to a top surface shape of a light-emitting region of a light-emitting device.

In the display apparatus including a light-emitting device and a light-receiving device in the pixel, the pixel has a light-receiving function, which enables detection of contact or approach of an object while an image is displayed. For example, all the subpixels included in the display apparatus can display an image; alternatively, some subpixels can emit light as a light source and the other subpixels can display an image.

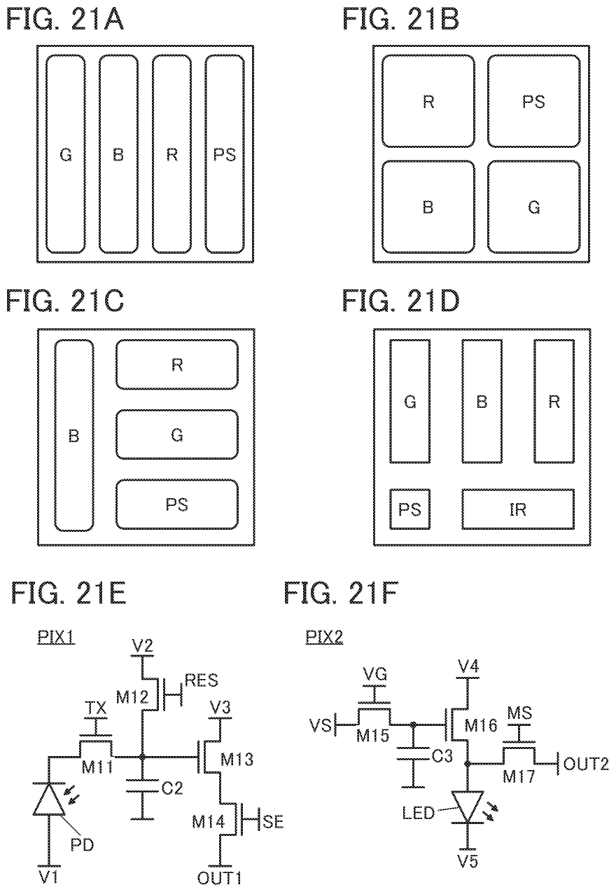

Pixels illustrated in FIG. 21A, FIG. 21B, and FIG. 21C each include a subpixel G, a subpixel B, a subpixel R, and a subpixel PS.

The pixel illustrated in FIG. 21A employs stripe arrangement. The pixel illustrated in FIG. 21B employs matrix arrangement.

The pixel arrangement illustrated in FIG. 21C has a structure in which three subpixels (the subpixel R, the subpixel G, and the subpixel PS) are vertically arranged next to one subpixel (the subpixel B).

The pixel illustrated in FIG. 21D includes the subpixel G, the subpixel B, the subpixel R, a subpixel IR, and the subpixel PS.

FIG. 21D illustrates an example in which one pixel is provided in two rows. Three subpixels (the subpixel G, the subpixel B, and the subpixel R) are provided in the upper row (first row), and two subpixels (one subpixel PS and one subpixel IR) are provided in the lower row (second row).

Note that the layout of the subpixels is not limited to the structures illustrated in FIG. 21A to FIG. 21D.

The subpixel R includes a light-emitting device that emits red light. The subpixel G includes a light-emitting device that emits green light. The subpixel B includes a light-emitting device that emits blue light. The subpixel IR includes a light-emitting device that emits infrared light. The subpixel PS includes a light-receiving device. Although the wavelength of light detected by the subpixel PS is not particularly limited, the light-receiving device included in the subpixel PS preferably has sensitivity to light emitted from the light-emitting device included in the subpixel R, the subpixel G, the subpixel B, or the subpixel IR. For example, the light-receiving device preferably detects one or more of light in blue, violet, bluish violet, green, yellowish green, yellow, orange, red, and infrared wavelength ranges, for example.

The light-receiving area of the subpixel PS is smaller than the light-emitting area of each of the other subpixels. A smaller light-receiving area leads to a narrower image-capturing range, inhibits a blur in a captured image, and improves the definition. Thus, the use of the subpixel PS enables high-resolution or high-definition image capturing. For example, image capturing for personal authentication with the use of a fingerprint, a palm print, the iris, the shape of a blood vessel (including the shape of a vein and the shape of an artery), or a face is possible by using the subpixel PS.

Moreover, the subpixel PS can be used in a touch sensor (also referred to as a direct touch sensor) or a near touch sensor (also referred to as a hover sensor, a hover touch sensor, a contactless sensor, or a touchless sensor). For example, the subpixel PS preferably detects infrared light. Thus, a touch can be detected even in a dark place.

Here, the touch sensor or the near touch sensor can detect approach or contact of an object (e.g., a finger, a hand, or a pen). The touch sensor can detect an object when the display apparatus and the object come in direct contact with each other. The near touch sensor can detect an object even when the object is not in contact with the display apparatus. For example, the display apparatus is preferably capable of detecting an object positioned in the range of 0.1 mm to 300 mm inclusive, more preferably 3 mm to 50 mm inclusive from the display apparatus. This structure enables the display apparatus to be operated without direct contact of an object. In other words, the display apparatus can be operated in a contactless (touchless) manner. With the above-described structure, the display apparatus can have a reduced risk of being dirty or damaged, or can be operated without the object directly touching dirt (e.g., dust or a virus) attached to the display apparatus.

Note that the contactless sensor function can also be referred to as a hover sensor function, a hover touch sensor function, a near touch sensor function, or a touchless sensor function. The touch sensor function can also be referred to as a direct touch sensor function.

The refresh rate of the display apparatus of one embodiment of the present invention can be variable. For example, the refresh rate is adjusted (adjusted in the range from 0.01 Hz to 240 Hz, for example) in accordance with contents displayed on the display apparatus, whereby power consumption can be reduced. Moreover, driving with a lowered refresh rate that reduces the power consumption of the display apparatus may be referred to as idling stop (IDS) driving.

The driving frequency of a touch sensor or a near touch sensor may be changed in accordance with the refresh rate described above. In the case where the refresh rate of the display apparatus is 120 Hz, for example, the driving frequency of the touch sensor or the near touch sensor can be higher than 120 Hz (typically 240 Hz). This structure reduces power consumption and increases the response speed of the touch sensor or the near touch sensor.

For high-resolution image capturing, the subpixel PS is preferably provided in all pixels included in the display apparatus. Meanwhile, in the case where the subpixel PS is used in a touch sensor or a near touch sensor, high accuracy is not required as compared to the case of capturing an image of a fingerprint; accordingly, the subpixel PS only needs to be provided in some of the pixels in the display apparatus. When the number of subpixels PS included in the display apparatus is smaller than the number of subpixels R, higher detection speed can be achieved.

FIG. 21E illustrates an example of the pixel circuit of the subpixel including a light-receiving device, and FIG. 21F illustrates an example of the pixel circuit of the subpixel including a light-emitting device.

A pixel circuit PIX1 illustrated in FIG. 21E includes a light-receiving device PD, a transistor M11, a transistor M12, a transistor M13, a transistor M14, and a capacitor C2. Here, an example in which a photodiode is used as the light-receiving device PD is illustrated.

An anode of the light-receiving device PD is electrically connected to a wiring V1 and a cathode of the light-receiving device PD is electrically connected to one of a source and a drain of the transistor M11. A gate of the transistor M11 is electrically connected to a wiring TX, and the other of the source and the drain of the transistor M11 is electrically connected to one electrode of the capacitor C2, one of a source and a drain of the transistor M12, and a gate of the transistor M13. A gate of the transistor M12 is electrically connected to a wiring RES, and the other of the source and the drain thereof is electrically connected to a wiring V2. One of a source and a drain of the transistor M13 is electrically connected to a wiring V3, and the other of the source and the drain thereof is electrically connected to one of a source and a drain of the transistor M14. A gate of the transistor M14 is electrically connected to a wiring SE, and the other of the source and the drain thereof is electrically connected to a wiring OUT1.

A constant potential is supplied to the wiring V1, the wiring V2, and the wiring V3. When the light-receiving device PD is driven with a reverse bias, a potential higher than the potential of the wiring V1 is supplied to the wiring V2. The transistor M12 is controlled by a signal supplied to the wiring RES and has a function of resetting the potential of a node connected to the gate of the transistor M13 to a potential supplied to the wiring V2. The transistor M11 is controlled by a signal supplied to the wiring TX and has a function of controlling the timing at which the potential of the node changes, in accordance with a current flowing through the light-receiving device PD. The transistor M13 functions as an amplifier transistor for performing output corresponding to the potential of the node. The transistor M14 is controlled by a signal supplied to the wiring SE and functions as a selection transistor for reading an output corresponding to the potential of the node by an external circuit connected to the wiring OUT1.

A pixel circuit PIX2 illustrated in FIG. 21F includes a light-emitting device LED, a transistor M15, a transistor M16, a transistor M17, and a capacitor C3. Here, an example in which a light-emitting diode is used as the light-emitting device LED is illustrated. In particular, a red light-emitting LED, a blue light-emitting LED, or a green light-emitting LED is preferably used as the light-emitting device LED.

A gate of the transistor M15 is electrically connected to a wiring VG, one of a source and a drain thereof is electrically connected to a wiring VS, and the other of the source and the drain thereof is electrically connected to one electrode of the capacitor C3 and a gate of the transistor M16. One of a source and a drain of the transistor M16 is electrically connected to a wiring V4, and the other of the source and the drain thereof is electrically connected to an anode of the light-emitting device LED and one of a source and a drain of the transistor M17. A gate of the transistor M17 is electrically connected to a wiring MS, and the other of the source and the drain thereof is electrically connected to a wiring OUT2. A cathode of the light-emitting device LED is electrically connected to a wiring V5.

A constant potential is supplied to the wiring V4 and the wiring V5. In the light-emitting device LED, the anode side can have a high potential and the cathode side can have a lower potential than the anode side. The transistor M15 is controlled by a signal supplied to the wiring VG and functions as a selection transistor for controlling a selection state of the pixel circuit PIX2. The transistor M16 functions as a driving transistor that controls current flowing through the light-emitting device LED, in accordance with a potential supplied to the gate. When the transistor M15 is in an on state, a potential supplied to the wiring VS is supplied to the gate of the transistor M16, and the emission luminance of the light-emitting device LED can be controlled in accordance with the potential. The transistor M17 is controlled by a signal supplied to the wiring MS and has a function of outputting a potential between the transistor M16 and the light-emitting device LED to the outside through the wiring OUT2.

Here, a transistor in which a metal oxide (an oxide semiconductor) is used in a semiconductor layer where a channel is formed is preferably used as each of the transistor M11. the transistor M12, the transistor M13, and the transistor M14 included in the pixel circuit PIX1 and the transistor M15, the transistor M16, and the transistor M17 included in the pixel circuit PIX2.

A transistor using a metal oxide having a wider band gap and a lower carrier density than silicon can achieve extremely low off-state current. Thus, such a low off-state current enables retention of charge accumulated in a capacitor that is connected in series with the transistor for a long time. For that reason, a transistor using an oxide semiconductor is preferably used particularly as the transistor M11, the transistor M12, and the transistor M15 each of which is connected in series with the capacitor C2 or the capacitor C3. Moreover, the use of transistors including an oxide semiconductor as the other transistors can reduce the manufacturing cost. Note that one embodiment of the present invention is not limited thereto. A transistor in which silicon is used in a semiconductor layer (hereinafter, also referred to as a Si transistor) may be used.

Note that the off-state current per micrometer of channel width of an OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current value per micrometer of channel width of a Si transistor at room temperature is higher than or equal to 1 fA (1×10⁻¹⁵ A) and lower than or equal to 1 pA (1×10⁻¹² A). In other words, the off-state current of the OS transistor is lower than that of the Si transistor by approximately ten orders of magnitude.

When transistors operate in a saturation region, a change in source-drain current relative to a change in gate-source voltage can be smaller in an OS transistor than in a Si transistor. Accordingly, when an OS transistor is used as the driving transistor in the pixel circuit, the amount of current flowing between the source and the drain can be set minutely by a change in gate-source voltage; hence, the amount of current flowing through the light-emitting device can be controlled. Therefore, the emission luminance of the light-emitting device can be controlled minutely (the number of gray levels in the pixel circuit can be increased).

Regarding saturation characteristics of current flowing when transistors operate in a saturation region, even in the case where the source-drain voltage of an OS transistor increases gradually, a more stable constant current (saturation current) can be fed through the OS transistor than through a Si transistor. Thus, by using an OS transistor as the driving transistor, a stable constant current can be fed through the light-emitting device LED even when the current-voltage characteristics of the light-emitting device LED vary, for example. In other words, when the OS transistor operates in the saturation region, the source-drain current hardly changes with an increase in the source-drain voltage; hence, the emission luminance of the light-emitting device can be stable.

As described above, by using an OS transistor as the driving transistor included in the pixel circuit, it is possible to inhibit black-level degradation, increase the emission luminance, increase the number of gray levels, and suppress variations in light-emitting devices, for example. Therefore, a display apparatus including the pixel circuit can display a clear and smooth image; as a result, any one or more of the image crispness, the image sharpness, and a high contrast ratio can be observed. When the driving transistor included in the pixel circuit has an extremely low off-state current, the display apparatus can perform black display with as little light leakage as possible (completely black display).

Alternatively, transistors including silicon in a semiconductor layer where a channel is formed can be used as the transistor M11 to the transistor M17. In particular, silicon with high crystallinity, typified by single crystal silicon or polycrystalline silicon, is preferably used, in which case high field-effect mobility is achieved and higher-speed operation is possible.

Alternatively, a transistor containing an oxide semiconductor (an OS transistor) may be used as at least one of the transistor M11 to the transistor M17, and transistors containing silicon (Si transistors) may be used as the other transistors. Note that as the Si transistor, a transistor containing low-temperature polysilicon (LTPS) (hereinafter, referred to as an LTPS transistor) can be used. A structure in which an OS transistor and an LTPS transistor are combined is referred to as LTPO in some cases. By employing LTPO in which an LTPS transistor with a high mobility and an OS transistor with a low off-state current are used, a display panel with high display quality can be provided.

Note that although n-channel transistors are illustrated as the transistors in FIG. 21E and FIG. 21F, p-channel transistors can alternatively be used.

The transistors included in the pixel circuit PIX1 and the transistors included in the pixel circuit PIX2 are preferably formed side by side over the same substrate. It is particularly preferable that the transistors included in the pixel circuit PIX1 and the transistors included in the pixel circuit PIX2 be periodically arranged in one region.

One or more layers including the transistor and/or the capacitor are preferably provided to overlap with the light-receiving device PD or the light-emitting device LED. Thus, the effective area occupied by each pixel circuit can be reduced, and a high-resolution light-receiving portion or display portion can be achieved.

At least part of this embodiment can be implemented in combination with the other embodiments described in this specification as appropriate.

### Embodiment 9

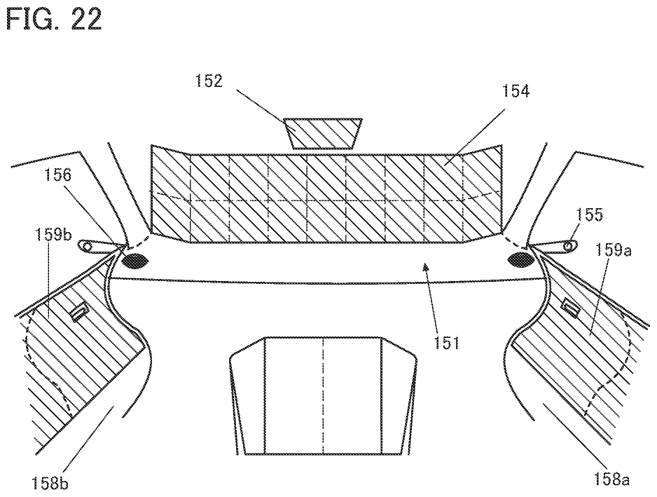

In this embodiment, electronic devices including the display apparatus of one embodiment of the present invention will be described with reference to FIG. 22.

This embodiment shows an example in which the display apparatus described in any one of Embodiments 1 to 4 is installed in a vehicle.

FIG. 22 is a diagram illustrating a structure example of a vehicle. FIG. 22 illustrates a dashboard 151 placed around a driver's seat, a display apparatus 154 fixed in front of the driver's seat, a camera 155, an outlet 156, a door 158a on the right side of the driver's seat, and a door 158b on the left side of the driver's seat. The display apparatus 154 extends in front of the driver's seat.

As the display apparatus 154 fixed in front of the driver's seat, the display apparatus in any one of Embodiments 1 to 4 can be used. FIG. 22 shows an example in which the display apparatus 154 is one display surface consisting of a combination of light-emitting devices in two rows and nine columns, i.e., 18 light-emitting devices in total. Although a boundary between pixel regions is indicated by a dotted line in FIG. 22, the dotted line is not displayed in an actual display image and a seam is not generated or is less noticeable. Moreover, the display apparatus 154 may have a see-through structure including a light-transmitting region through which the outside can be seen.

The display apparatus 154 is preferably provided with a touch sensor or a non-contact proximity sensor. Alternatively, the display apparatus 154 is preferably capable of being operated by gestures with use of a camera that is separately provided.

Although FIG. 22 illustrates a vehicle capable of autonomous driving having no handle (also referred to as steering wheel), one embodiment of the present invention is not particularly limited thereto, and the handle may be provided with a display apparatus having a curved surface; in that case, the structure shown in Embodiment 2 can be employed.

In addition, a plurality of cameras 155 that take pictures of the situations at the rear side may be provided outside the vehicle. Although the camera 155 is provided instead of a side mirror in the example in FIG. 22, both the side mirror and the camera may be provided. As the camera 155, a CCD camera or a CMOS camera can be used. In addition, an infrared camera may be used in combination with such a camera. The infrared camera, which has a higher output level with a higher temperature of an object, can detect or extract a living body (a human or an animal).

An image taken by the camera 155 can be output to the display apparatus 154. The display apparatus 154 is mainly used for supporting driving of the vehicle. An image of the situation on the rear side is taken at a wide angle of view by the camera 155, and the image is displayed on the display apparatus 154 so that the driver can see a blind area to avoid an accident.

Furthermore, a distance image sensor may be provided over a roof of the vehicle, for example, and an image obtained by the distance image sensor may be displayed on the display apparatus 154. For the distance image sensor, an image sensor or LIDAR (Light Detection and Ranging) can be used. An image obtained by the image sensor and the image obtained by the distance image sensor are displayed on the display apparatus 154, whereby more information can be provided to the driver to support driving.

In addition, a display apparatus 152 having a curved surface can be provided inside a roof of the vehicle, that is, in a roof portion. In the case where the display apparatus 152 having a curved surface is provided in the roof portion, the display apparatus described in Embodiment 1 or Embodiment 2 can be used.

The display apparatus 152 and the display apparatus 154 may also have a function of displaying map information, traffic information, television images, and DVD images.

The image displayed on the display apparatus 154 can be freely set to meet the driver's preference. For example, television images, DVD images, or online videos can be displayed on an image region on the left side, map information can be displayed on an image region at the center, and meters typified by a speed meter and a tachometer can be displayed on an image region on the right side.

In FIG. 22, a display apparatus 159a and a display apparatus 159b are provided along a surface of the door 158a on the right side and a surface of the door 158b on the left side, respectively. The display apparatus 159a and the display apparatus 159b can each be formed using one or more light-emitting devices. For example, one display surface is formed using light-emitting devices in one row and two columns.

The display apparatus 159a and the display apparatus 159b are placed to face each other.

A display apparatus having an image capturing function is preferably used as at least one of the display apparatuses 152, 154, 159a, and 159b.

For example, when the driver touches an image region of at least one of the display apparatuses 152, 154, 159a, and 159b, biological authentication such as fingerprint authentication or palm print authentication can be performed in the vehicle. The vehicle may have a function of setting an environment to meet the driver's preference when the driver is authenticated by biometric authentication. For example, one or more of adjustment of the position of the seat, adjustment of the position of the steering wheel, adjustment of the direction of the cameras 155, setting of brightness, setting of an air conditioner, setting of the speed (frequency) of wipers, volume setting of audio, and read processing of the playlist of the audio are preferably performed after authentication.

Alternatively, an automobile can be automatically brought into a state where the automobile can be driven, e.g., a state where an engine is started or a state where an electric vehicle can be started, after the driver is authenticated by biological authentication. This is preferable because a key, which is conventionally necessary, is unnecessary.

Although the display apparatus that surrounds the driver's seat is described here, a display apparatus can be provided to surround also a passenger on a rear seat.

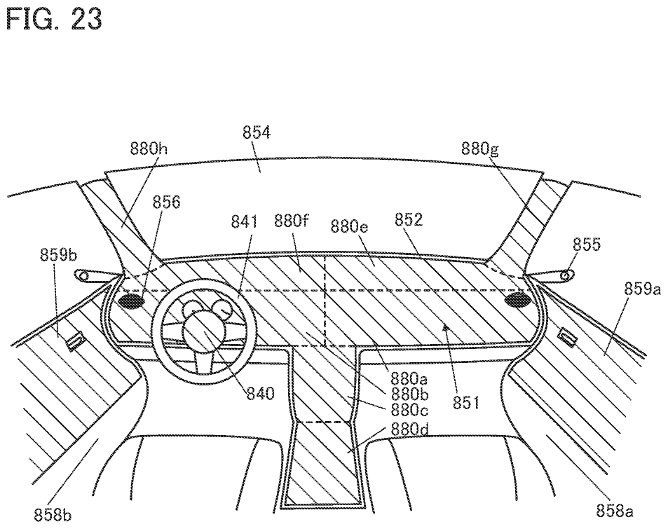

Another example is described with reference to FIG. 23.

FIG. 23 is a diagram illustrating a structure example of a vehicle. FIG. 23 illustrates a dashboard 852 placed around a driver's seat and a front passenger's seat, a steering wheel 841, a windshield 854, a camera 855, an outlet 856, a front-passenger-side door 858a, and a driver-side door 858b. A display portion 851 is provided horizontally across the dashboard 852.

The steering wheel 841 includes a light-emitting and light-receiving portion 840. The light-emitting and light-receiving portion 840 has a function of emitting light and a function of capturing an image. The light-emitting and light-receiving portion 840 enables biological information such as a fingerprint, a palmprint, or a vein of a driver to be obtained; the driver can be authenticated on the basis of the biological information. Therefore, only drivers registered in advance are allowed to start the vehicle, resulting in a vehicle with an extremely high security level.

In addition, a plurality of cameras 855 that take pictures of the situations at the rear side may be provided outside the vehicle. Although the camera 855 is provided instead of a side mirror in the example in FIG. 23, both the side mirror and the camera may be provided. As the camera 855, a CCD camera or a CMOS camera can be used. In addition, an infrared camera may be used in combination with such a camera. The infrared camera, which has a higher output level with a higher temperature of an object, can detect or extract a living body (a human or an animal).

An image taken by the camera 855 can be output to one or both of the display portion 851 and the light-emitting and light-receiving portion 840. The display portion 851 or the light-emitting and light-receiving portion 840 is mainly used for supporting driving of the vehicle. An image of the situation on the rear side is taken at a wide angle of view by the camera 855, and the image is displayed on the display portion 851 or the light-emitting and light-receiving portion 840 so that the driver can see a blind area to avoid an accident.

The display portion 851 may also have a function of displaying map information, traffic information, television images, and DVD images. For example, map information can be displayed on a display panel 880a and a display panel 880b as a large display screen. Note that the number of display panels can be increased depending on the image to be displayed.

In FIG. 23, the display portion 851 is provided on the dashboard, a center console, and left and right pillars. In the example illustrated in FIG. 23, the display portion 851 includes eight display panels (the display panel 880a to a display panel 880h); however, the number of display panels is not limited thereto and may be seven or less or nine or more. A display panel 880c and a display panel 880d are provided in a position corresponding to the center console. Here, a combination of the display panel 880d and the display panel 880c with a non-rectangular shape is shown. In the case where the display panel 880d with a rectangular shape and the display panel 880c are combined to be used as one panel, a resulting panel is a non-rectangular panel as a whole. A display panel 880e and a display panel 880f are provided on the far side of the dashboard from the driver. A display panel 880g and the display panel 880h are provided along the pillars. One or more of the display panel 880a to the display panel 880h are provided along a curved surface.

Images to be displayed on the display panel 880a to the display panel 880h can be freely set according to the driver's preference. For example, television images, DVD images, or online videos can be displayed on the display panel 880a and the display panel 880e on the right side; map information can be displayed on the display panel 880c at the center; meters such as a speedometer and a tachometer can be displayed on the display panel 880b and the display panel 880f on the driver side; and audio information can be displayed on the display panel 880d between the driver's seat and the front passenger's seat. External views in the driver's line of sight are displayed in real time on the display panel 880g and the display panel 880h provided on the pillars, which enables the vehicle to be a pseudo-pillarless vehicle and to have fewer blind spots, resulting in a highly safe vehicle.

Furthermore, in FIG. 23, a display portion 859a and a display portion 859b are provided along a surface of the front-passenger-side door 858a and a surface of the driver-side door 858b, respectively. Each of the display portion 859a and the display portion 859b can be formed using one or more display panels.

The display portion 859a and the display portion 859b are placed to face each other, and the display portion 851 is provided on the dashboard 852 so as to connect an end portion of the display portion 859a and an end portion of the display portion 859b. Accordingly, a driver and a passenger in the front passenger's seat are surrounded by the display portion 851, the display portion 859a, and the display portion 859b in the front and on both sides. For example, displaying one image across the display portion 859a, the display portion 851, and the display portion 859b enables the driver or the passenger to have an enhanced sense of immersion.

In addition, the plurality of cameras 855 that capture images of the situations on the rear side may be provided outside the vehicle. Although the camera 855 is provided instead of a side mirror in the example in FIG. 23, both the side mirror and the camera may be provided.

As the camera 855, a CCD camera or a CMOS camera can be used. In addition, an infrared camera may be used in combination with such a camera. The infrared camera, which has a higher output level with a higher temperature of an object, can detect or extract a living body (a human or an animal).

An image captured by the camera 855 can be output to any one or more of the display panels. The image displayed on the display portion 851 can be mainly used for supporting driving of the vehicle. For example, an image of the situation on the rear side is captured at a wide angle of view by the camera 855, and the image is displayed on any one or more of the display panels so that the driver can see a blind area to avoid an accident.

In addition, the display portion 859a and the display portion 859b can display an image synchronized with the scenery from the window, which is obtained by synthesizing images obtained by the camera 855. That is, an image that the driver and the passenger can see through the door 858a and the door 858b can be displayed on the display portion 859a and the display portion 859b. This allows the driver and the passenger to experience the sensation of floating.

A display panel having an image capturing function is preferably used as at least one of the display panel 880a to the display panel 880h. Furthermore, a display panel having an image capturing function can also be used as one or more of the display panels provided in the display portion 859a and the display portion 859b.

As described above, the structure of one embodiment of the present invention can increase the degree of flexibility in design of a display apparatus and thus can improve the design of the display apparatus. The display apparatus of one embodiment of the present invention can be suitably installed in a vehicle.

At least part of this embodiment can be implemented in combination with the other embodiments described in this specification as appropriate.

### Embodiment 10

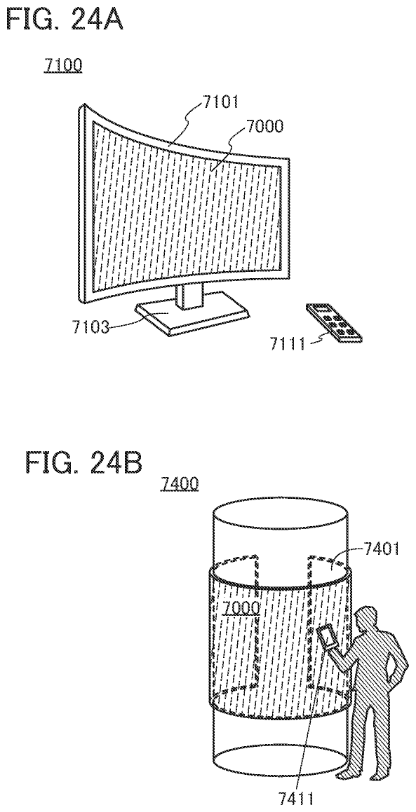

In this embodiment, electronic devices of one embodiment of the present invention will be described with reference to FIG. 24A and FIG. 24B.

An electronic device of this embodiment includes the display apparatus of one embodiment of the present invention in a display portion. The display apparatus of one embodiment of the present invention can be easily increased in resolution and definition. Thus, the display apparatus of one embodiment of the present invention can be used for a display portion of a variety of electronic devices.

Examples of electronic devices include a digital camera, a digital video camera, a digital photo frame, a mobile phone, a portable game console, a portable information terminal, and an audio reproducing device in addition to electronic devices with a relatively large screen, such as a television device, a desktop or laptop personal computer, a monitor of a computer, digital signage, and a large game machine typified by a pachinko machine.

In particular, a display apparatus of one embodiment of the present invention can have a high resolution, and thus can be favorably used for an electronic device having a relatively small display portion. Examples of such an electronic device include a watch-type or a bracelet-type information terminal device (wearable device), and a wearable device worn on a head, such as a device for VR such as a head mounted display, a glasses-type device for AR, and a device for MR.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the definition is preferably 4K, 8K, or higher. Furthermore, the pixel density (resolution) of the display apparatus of one embodiment of the present invention is preferably higher than or equal to 100 ppi, higher than or equal to 300 ppi, further preferably higher than or equal to 500 ppi, still further preferably higher than or equal to 1000 ppi, still further preferably higher than or equal to 2000 ppi, still further preferably higher than or equal to 3000 ppi, still further preferably higher than or equal to 5000 ppi, and yet further preferably higher than or equal to 7000 ppi. With the use of such a display apparatus with high definition and high resolution, the electronic device can have higher realistic sensation and sense of depth in personal use such as portable use and home use. There is no particular limitation on the screen ratio (aspect ratio) of the display apparatus of one embodiment of the present invention. For example, the display apparatus is compatible with a variety of screen ratios (e.g., 1:1 (a square), 4:3, 16:9, and 16:10).

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

FIG. 24A illustrates an example of a television device. In a television device 7100, a display portion 7000 is incorporated in a housing 7101. Here, the housing 7101 is supported by a stand 7103.

The display apparatus of one embodiment of the present invention can be used in the display portion 7000. The display apparatus in any one of Embodiments 1 to 3 can be used in the display portion 7000 having a curved surface.

Operation of the television device 7100 illustrated in FIG. 24A can be performed with an operation switch provided in the housing 7101 and a separate remote controller 7111. Alternatively, the display portion 7000 may include a touch sensor, and the television device 7100 may be operated by touch on the display portion 7000 with a finger. The remote controller 7111 may be provided with a display portion for displaying information output from the remote controller 7111. With operation keys or a touch panel provided in the remote controller 7111, channels and volume can be operated and videos displayed on the display portion 7000 can be operated.

Note that the television device 7100 has a structure in which a receiver and a modem are provided. A general television broadcast can be received with the receiver. When the television device is connected to a communication network with or without wires via the modem, one-way (from a transmitter to a receiver) or two-way (between a transmitter and a receiver or between receivers) data communication can be performed.

FIG. 24B illustrates an example of digital signage.

FIG. 24B is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 in FIG. 24B.

A larger area of the display portion 7000 can increase the amount of information that can be provided at a time. The larger display portion 7000 attracts more attention, so that the effectiveness of the advertisement can be increased, for example.

The use of a touch panel in the display portion 7000 is preferable because in addition to display of a still image or a moving image on the display portion 7000, intuitive operation by a user is possible. Moreover, for an application for providing route information or traffic information, usability can be enhanced by intuitive operation.

As illustrated in FIG. 24B, it is preferable that the digital signage 7400 can work with an information terminal 7411, which is a smartphone a user has, through wireless communication. For example, information of an advertisement displayed on the display portion 7000 can be displayed on a screen of the information terminal 7411. By operation of the information terminal 7411, display on the display portion 7000 can be switched.

It is possible to make the digital signage 7400 execute a game with use of the screen of the information terminal 7411 as an operation means (controller). Thus, an unspecified number of users can join in and enjoy the game concurrently.

This embodiment can be combined with the other embodiments as appropriate.

### REFERENCE NUMERALS

10: support, 11: support, 12a: third substrate, 12b: fourth substrate, 12: substrate, 13: cover member, 14b: light-emitting direction, 15: region, 16a: light-emitting panel, 16b: light-emitting panel, 16c: light-emitting panel, 16d: light-emitting panel, 16e: fifth light-emitting panel, 16f: sixth light-emitting panel, 16g: seventh light-emitting panel, 16h: eighth light-emitting panel, 17B: light-emitting element, 17G: light-emitting element, 17R: light-emitting element, 17: light-emitting diode chip, 18a: nitride film, 18b: nitride film, 19: resin, 21: electrode, 23: electrode, 51A: LED chip compartment, 51B: LED chip, 51: LED chip, 71A: substrate, 71: substrate, 75a: n-type contact layer, 75b: n-type clad layer, 75: n-type semiconductor layer, 77a: barrier layer, 77b: well layer, 77: light-emitting layer, 79a: p-type clad layer, 79b: p-type contact layer, 79: p-type semiconductor layer, 81: semiconductor layer, 83: electrode, 85: electrode, 87: electrode, 89: insulating layer, 103: pixel, 110a: subpixel, 110b: subpixel, 110c: subpixel, 110d: subpixel, 151: dashboard, 152: display apparatus, 154: display apparatus, 155: camera, 156: outlet, 158a: door, 158b: door, 159a: display apparatus, 159b: display apparatus, 401: substrate, 410a: transistor, 410: transistor, 411i: channel formation region, 411n: low-resistance region, 411: semiconductor layer, 412: insulating layer, 413: conductive layer, 414a: conductive layer, 414b: conductive layer, 415: conductive layer, 416: insulating layer, 421: insulating layer, 422: insulating layer, 423: insulating layer, 426: insulating layer, 431: conductive layer, 450a: transistor, 450: transistor, 451: semiconductor layer, 452: insulating layer, 453: conductive layer, 454a: conductive layer, 454b: conductive layer, 455: conductive layer, 610: display apparatus, 611: display portion, 612: driver circuit portion, 613: driver circuit portion, 621B: subpixel, 621G: subpixel, 621R: subpixel, 621: pixel, 630: pixel, 700A: display apparatus, 700: laser irradiation line, 702: pixel region, 704: gate driver circuit portion, 706: source driver circuit portion, 710: signal line, 711: lead wiring portion, 732: resin, 736: coloring layer, 738: light-blocking layer, 740: second substrate, 742: adhesive layer, 743: resin layer, 744: insulating layer, 745: first substrate, 750: transistor, 752: transistor, 770: insulating layer, 772: conductive layer, 774: conductive layer, 782: light-emitting element, 790: capacitor, 791: bump, 793: bump, 795: resin layer, 797: phosphor layer, 800: flexible substrate, 801: second substrate, 810: flexible substrate, 811: second substrate, 820: element layer, 821: element layer, 840: light-emitting and light-receiving portion, 841: steering wheel, 851: display portion, 852: dashboard, 854: windshield, 855: camera, 856: outlet, 858a: door, 858b: door, 859a: display portion, 859b: display portion, 880a: display panel, 880b: display panel, 880c: display panel, 880d: display panel, 880e: display panel, 880f: display panel, 880g: display panel, 880h: display panel, 900: LED chip substrate, 901: film, 903: plate, 905: table, 907: grinding stone, 909: grinding stone wheel, 911: scribe line, 913: base, 914: opening portion, 915: blade, 919: first film, 921: first fixture, 923: sheet, 924: plate, 925: second fixture, 927: second film, 929: extrusion mechanism, 950: apparatus, 951: stage, 953: one-axis robot, 955: one-axis robot, 957: camera, 959: grasping mechanism, 961: control device, 963: unit, 7000: display portion, 7100: television device, 7101: housing, 7103: stand, 7111: remote controller, 7400: digital signage, 7401: pillar, 7411: information terminal

1. An electronic device comprising:
a plurality of flexible substrates;
a plurality of light-emitting diode chips mounted over each of the plurality of flexible substrates;
a substrate provided with a nitride film; and
a resin between the plurality of flexible substrates and the substrate provided with the nitride film,
wherein light emitted from the plurality of light-emitting diode chips passes through the substrate provided with the nitride film.

2. The electronic device according to claim 1, wherein the plurality of flexible substrates have a light-transmitting property.

3. The electronic device according to claim 1, wherein end portions of adjacent flexible substrates among the plurality of flexible substrates overlap with each other.

4. The electronic device according to claim 1, wherein the substrate provided with the nitride film has a light-transmitting property.

5. The electronic device according to claim 1, wherein the resin has a light-transmitting property.

6. The electronic device according to claim 1, wherein the nitride film is a silicon nitride film.

7. The electronic device according to claim 1, wherein the plurality of light-emitting diode chips each include a micro light-emitting diode.

8. An electronic device comprising:
a first flexible substrate;
a second flexible substrate adjacent to the first flexible substrate;
a plurality of light-emitting diode chips mounted over the first flexible substrate and the second flexible substrate;
a substrate provided with a nitride film; and
a resin between the first flexible substrate and the substrate provided with the nitride film,
wherein light emitted from the plurality of light-emitting diode chips passes through the substrate provided with the nitride film, and
wherein an end portion of the first flexible substrate overlaps with an end portion of the second flexible substrate.

9. The electronic device according to claim 8, wherein the first flexible substrate and the second flexible substrate each have a light-transmitting property.

10. The electronic device according to claim 8, wherein the substrate provided with the nitride film has a light-transmitting property.

11. The electronic device according to claim 8, wherein the resin has a light-transmitting property.

12. The electronic device according to claim 8, wherein the nitride film is a silicon nitride film.

13. The electronic device according to claim 8, wherein the plurality of light-emitting diode chips each include a micro light-emitting diode.
